(19) United States
(12) Patent Application Publication
(10) Pub. No.: US 2026/0206554 A1
(43) Pub. Date: Jul. 16, 2026

(54) BACK-SIDE IMPLANTATION AND NANOSECOND LASER ANNEALING FOR SOURCE/DRAIN REGIONS

(71) Applicant: TAIWAN SEMICONDUCTOR MANUFACTURING COMPANY, LTD., Hsinchu (TW)

(72) Inventors: Yi-Rui CHEN, Yilan County (TW); Yu-Chang LIN, Hsinchu City (TW); Ji-Yin TSAI, Hsinchu County (TW)

(73) Assignee: TAIWAN SEMICONDUCTOR MANUFACTURING COMPANY, LTD., Hsinchu (TW)

(21) Appl. No.: 19/024,417

(22) Filed: Jan. 16, 2025

(51) Int. Cl. H01L 21/324; H01L 21/02; H01L 21/265; H01L 21/306; H01L 21/308; H10D 30/01; H10D 62/10; H10D 64/01

(52) U.S. Cl. CPC H10P 95/90; H10D 30/014; H10D 30/0191; H10P 14/3411; H10P 14/3822; H10P 30/204; H10P 30/212; H10D 62/121; H10D 64/017; H10P 50/642; H10P 50/691

(57) ABSTRACT

A method includes a backside implantation process introduces high dopant concentrations into the source/drain regions from the back-sides of the source/drain regions, creating an amorphous backside implanted region. To activate dopants without affecting front-side components, a nanosecond laser annealing (NSA) process is applied. The NSA process uses lasers with wavelengths shorter than 400 nm. This causes localized heating within about 10 nm of the surface, activating dopants and recrystallizing part of the amorphous region into crystalline region, while thinning the remaining amorphous region. Subsequently, a metal silicidation process then can form a backside silicide layer in the thin amorphous region. Then, backside contacts can be formed over the backside silicide layer. This backside processing can enhance electrical performance by improving dopant activation and reducing contact resistance while preserving the integrity of front-side components.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic perspective view of a semiconductor structure, in accordance with some embodiments of the present disclosure.

FIGS. 2-10B illustrate cross-sectional views of intermediate stages, in the formation of a semiconductor structure in accordance with some embodiments.

FIGS. 11A-11F illustrate cross-sectional views of intermediate stages in the formation of a contact in an epitaxial source/drain region of a semiconductor structure, in accordance with some embodiments of the present disclosure.

FIG. 12A illustrates penetration depths of different laser wavelengths into a semiconductor substrate, in accordance with some embodiments of the present disclosure.

FIG. 12B illustrates a comparison of dopant concentration profiles with and without nanosecond laser annealing (NSA) process on source/drain region of a semiconductor structure, in accordance with some embodiments of the present disclosure.

FIG. 13A shows the effect of NSA process with varying shot numbers on active dopant concentration (1/cm³) in epitaxial n-type source/drain region, in accordance with some embodiments of the present disclosure.

FIG. 13B shows the effect of NSA process with varying shot numbers on reducing sheet resistance (i.e., Rs (Ohm/sq)) in epitaxial p-type source/drain region, in accordance with some embodiments of the present disclosure.

FIGS. 14A and 14B show the effect of NSA on active dopant concentration (1/cm³) for low and high dopant concentration in epitaxial n-type source/drain region, in accordance with some embodiments of the present disclosure.

FIGS. 14C and 14D show the effect of NSA on reducing sheet resistance (i.e., Rs (Ohm/sq)) for low and high dopant concentration in epitaxial p-type source/drain region, in accordance with some embodiments of the present disclosure.

FIG. 15 illustrates a schematic perspective view of example stacking transistor in accordance with some embodiments.

FIGS. 16-24B illustrate cross-sectional views of intermediate stages in the formation of a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In some embodiments, a back end of line (BEOL) processes can have a thermal budget limit of 400° C., which is insufficient for effective dopant activation that requires temperatures above 700° C. Existing annealing methods are inadequate because they either heat the metal components or the entire structure, leading to potential damage and preventing efficient dopant activation between the backside metal and the source/drain epitaxial (i.e., S/D EPI) layers, resulting in high contact resistance and degraded device performance.

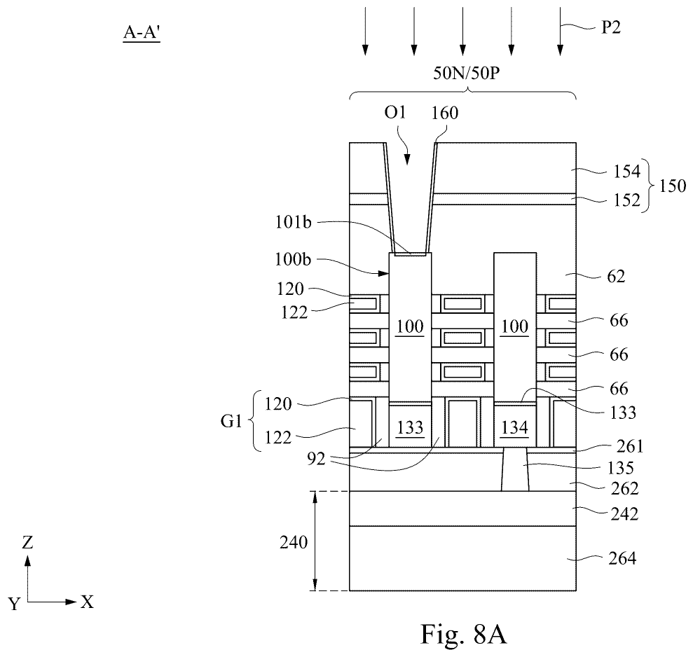

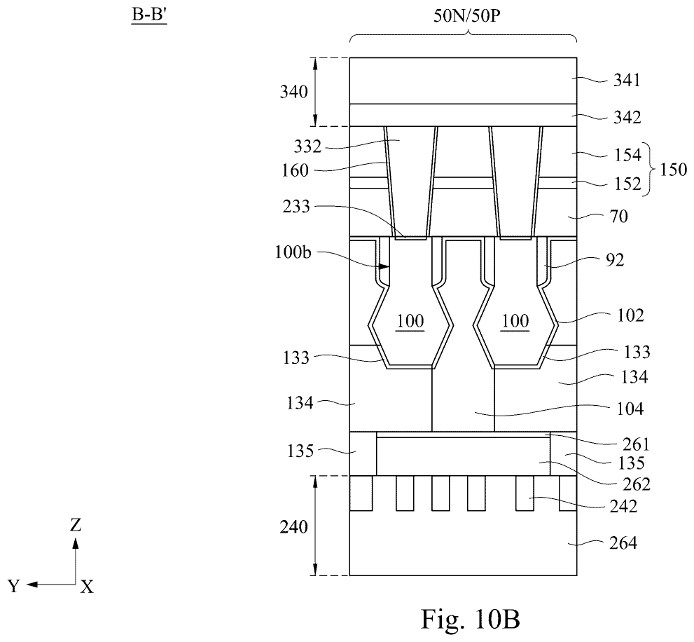

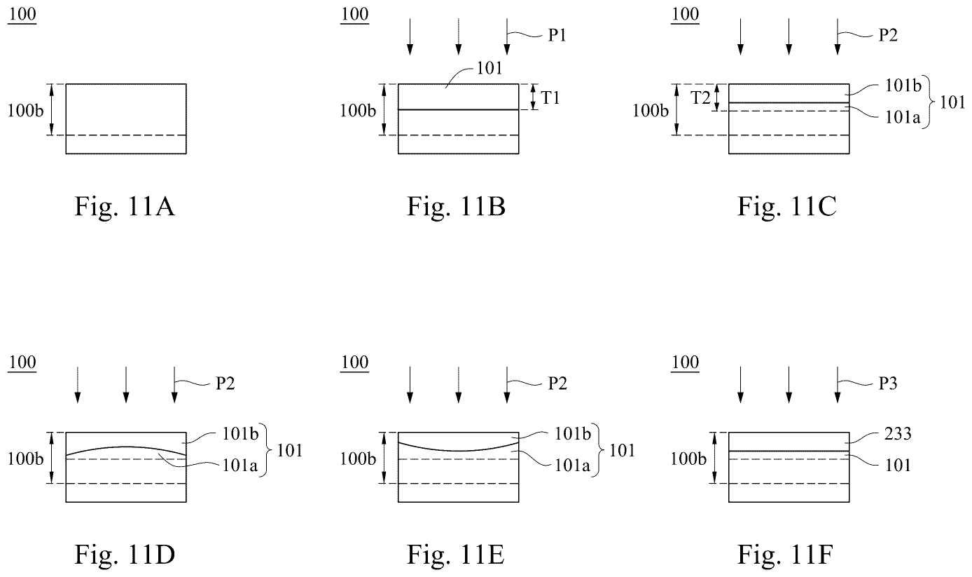

Therefore, the present disclosure in various embodiments provides a nanosecond laser annealing (NSA) process (see FIGS. 8A, 8B, and 11C) using a laser with a wavelength below 400 nm. This can allow for high-temperature surface heating above 900° C. within a shallow depth of less than 10 nm, effectively activating dopants without damaging front-side metal components. The NSA process can ensure a high dopant concentration at the interface between silicide and epitaxial silicon (e.g., n-type or p-type EPI). Therefore, the NSA process can effectively activate dopants without affecting deeper layers, thereby protecting the front-side metal components. In some embodiments, the NSA process can integrate into gate-all-around (GAA) and complementary field effect transistor (CFET) technologies in semiconductor devices.

Furthermore, a multi-shot NSA process can repair implant damage using a lower thermal budget and prevent damage to bottom metal layers. In some embodiments, implant species, such as boron (B), gallium (Ga), phosphorus (P), and arsenic (As), can be used in conjunction with NSA process to enhance dopant activation. In some embodiments, for medium germanium content (e.g., 40-60% in SiGe), gallium implantation followed by NSA process can offer better resistivity reduction compared to bron implantation. In high Ge content (e.g., 60-80% in SiGe), phosphorus or arsenic implantation can achieve lower sheet resistance (Rs). Therefore, this invention can effectively reduce contact resistivity in backside vias, which in turn improves the performance and reliability of semiconductor devices while operating within the thermal constraints of BEOL processes.

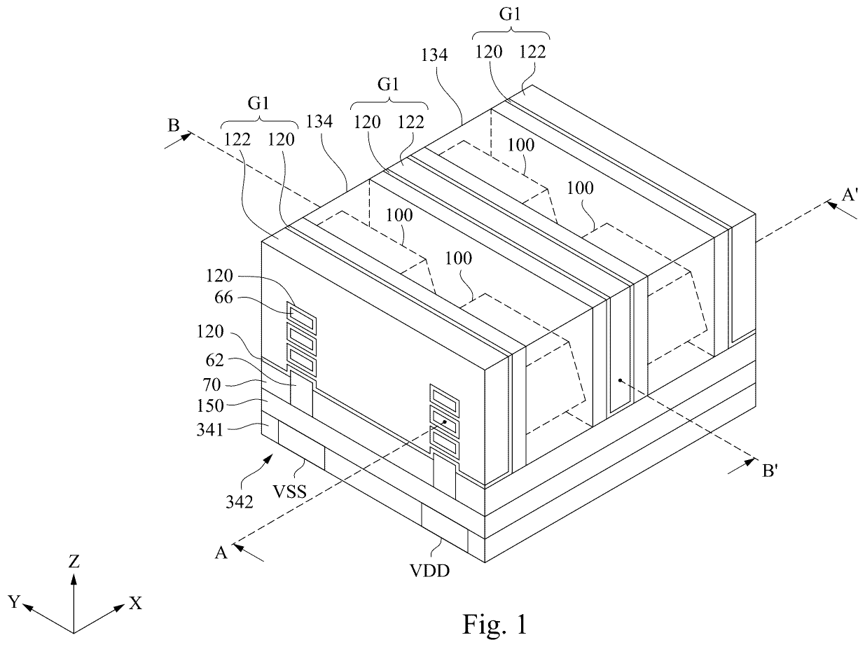

Reference is made to FIG. 1. FIG. 1 illustrates an example of nanostructure-FETs (e.g., nanowire FETs, nanosheet FETs, nano-FETs, or the like), gate-all-around (GAA) FETs, or the like) in a three-dimensional view in accordance with some embodiments of the present disclosure.

FIG. 1 illustrates an example of nanostructure-FETs (e.g., nanowire FETs, nanosheet FETs, nano-FETs, or the like), gate-all-around (GAA) FETs, or the like) in a three-dimensional view, in accordance with some embodiments. Some features of the nanostructure-FETs may be simplified and/or omitted in FIG. 1 for clarity. The nanostructure-FETs comprise nanostructures 66 (e.g., nanosheets, nanowires, or the like) over fin structures 62, with the nanostructures 66 being semiconductor features that act as channel regions for the nanostructure-FETs. The nanostructures 66 may include p-type nanostructures, n-type nanostructures, or a combination thereof. Isolation regions 70, such as shallow trench isolation (STI) regions, are disposed between adjacent fin structures 62, which may protrude above and from between neighboring isolation regions 70. The nanostructures 66 are disposed over and between adjacent isolation regions 70.

The gate dielectric layers 120 are over top surfaces of the fin structures 62 and along top surfaces, sidewalls, and bottom surfaces of the nanostructures 66. Gate electrode layers 122 are over the gate dielectric layers 120. The gate dielectric layers 120 and the gate electrode layers 122 may be collectively be called “gate structures” or “gate stacks.” Source/drain regions 100 can be disposed on the fin structures 62 at opposing sides of the gate dielectric layers 120 and the gate electrodes 122. Source/drain region(s) 100 may refer to a source or a drain, individually or collectively dependent upon the context. An inter-layer dielectric (ILD) 104 is formed over the source/drain regions 100. Contacts (subsequently described) to the source/drain regions 100 will be formed through the ILD 104. The source/drain regions 100 may be shared between various nanostructures 66. For example, adjacent source/drain regions 100 may be electrically connected, such as through coalescing or merging the source/drain regions 100 by epitaxial growth, or through coupling the source/drain regions 100 with a same contact.

FIG. 1 further illustrates reference cross-sections that are used in later figures. Cross-section A-A′ in FIG. 1 is parallel to a longitudinal axis of the nanostructure 66 and in a direction of, for example, a current flow between the source/drain regions 100. Cross-section B-B′ in FIG. 1 is parallel to a longitudinal axis of the metal gate structure G1 including the gate dielectric layer 120 and the gate electrode layer 122. Subsequent figures refer to these reference cross-sections for clarity. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs. Other FETs or configurations of FETs are possible.

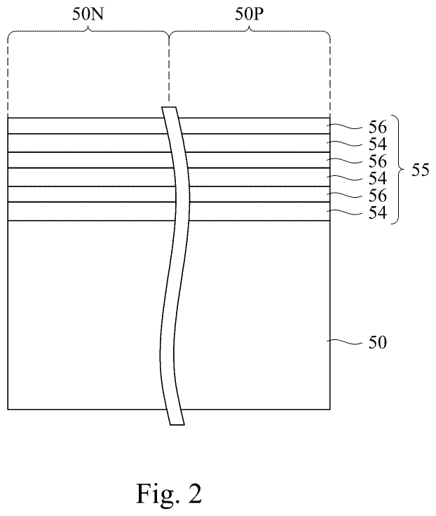

Reference is made to FIGS. 2-11F. FIGS. 2-10B illustrate cross-sectional views of intermediate stages in the formation of a semiconductor structure in accordance with some embodiments. FIGS. 2, 3A, 4A, 4B, 5A, 6A, 7A, 7B, 8A, 9A, and 10A illustrate cross-sectional views obtained from reference cross-sections A-A′ in FIG. 1, and FIGS. 2, 3B, 4C, 5B, 6B, 7B, 7C, 8B, 9B, and 10B illustrate cross-sectional views obtained from reference cross-sections B-B′ in FIG. 1. FIGS. 11A-11F illustrate cross-sectional views of intermediate stages in the formation of a contact in a source/drain region of a semiconductor structure in accordance with some embodiments of the present disclosure. It is understood that additional operations can be provided before, during, and after the processes shown by FIGS. 2-11F, and some of the operations described below can be replaced or eliminated, for additional embodiments of the method. The order of the operations/processes may be interchangeable.

Reference is made to FIG. 2. The substrate 50 may be a semiconductor substrate, such as a bulk semiconductor, a semiconductor-on-insulator (SOI) substrate, or the like, which may be doped (e.g., with a p-type or an n-type dopant) or un-doped. The substrate 50 may be a wafer, such as a silicon wafer. An SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 can have a first conductivity type device region 50N and a second conductivity type device region 50P. The first conductivity type device region 50N can be for forming n-type devices, such as NMOS transistors, e.g., n-type nanostructure-FETs, and the second conductivity type device region 50P can be for forming p-type devices, such as PMOS transistors, e.g., p-type nanostructure-FETs. The first conductivity type device region 50N may (or may not) be physically separated (not separately illustrated) from the second conductivity type device region 50P, and any number of device features (e.g., other active devices, doped regions, isolation structures, etc.) may be disposed between the first conductivity type device region 50N and the second conductivity type device region 50P. Although one first conductivity type device region 50N and one second conductivity type device region 50P are illustrated, any number of n-type regions 50N and p-type regions 50P may be provided. Subsequent figures describe processing steps that may be performed in either the n-type regions 50N or the p-type regions 50P unless otherwise noted.

A multi-layer stack 55 can be formed over the substrate 50, in accordance with some embodiments. The multi-layer stack 55 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, and as subsequently described in greater detail, the first semiconductor layers 54 will be removed and the second semiconductor layers 56 will patterned to form channel regions for the nanostructure-FETs in both the first conductivity type device region 50N and the second conductivity type device region 50P. In such embodiments, the channel regions in both the first conductivity type device region 50N and the second conductivity type device region 50P may have a same material composition (e.g., silicon or another semiconductor material) and be formed simultaneously. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon. The first semiconductor material and the second semiconductor material may have a high etching selectivity from the etching of one another.

The multi-layer stack 55 can be illustrated as including three of the first semiconductor layers 54 and three of the second semiconductor layers 56. It should be appreciated that the multi-layer stack 55 may include any number of the first semiconductor layers 54 and the second semiconductor layers 56. Each of the layers of the multi-layer stack 55 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 55 are formed to be thinner than other layers of the multi-layer stack 55. For example, in other embodiments, the bottom-most second semiconductor layer 56 (e.g., the second semiconductor layer 56 closest to the substrate 50) may be thinner than overlying second semiconductor layers 56 to improve short channel control in the resulting nanostructure-FETs. Other combinations or variations of layer thicknesses are possible.

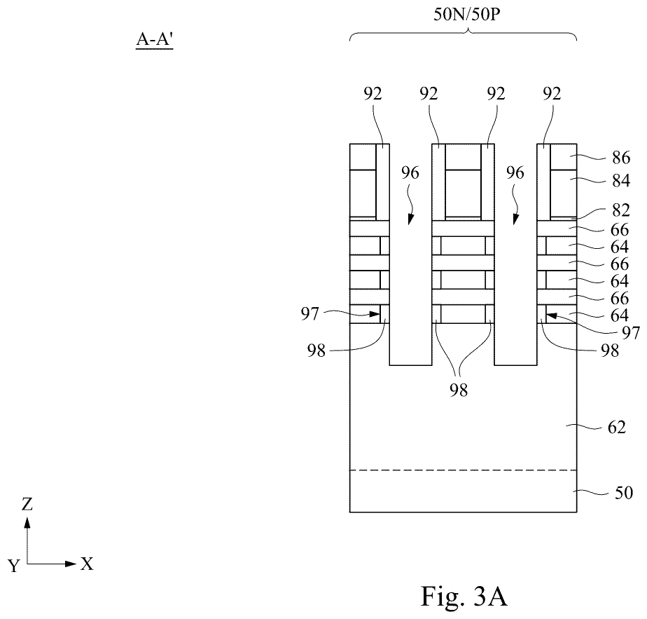

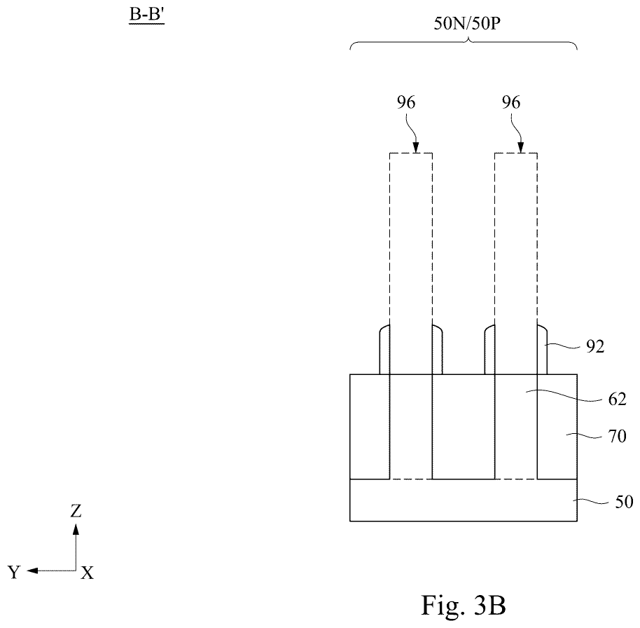

Reference is made to FIGS. 3A and 3B. Fin structures 62 can be formed in the substrate 50, and first nanostructures 64 and second nanostructures 66 can be formed in the multi-layer stack 55, by etching trenches in the multi-layer stack 55 and the substrate 50. In some cases, the nanostructures 64/66 over the fin structure 62 may be considered a nanostructure stack or the like. FIGS. 3A and 3B may be in either of the first conductivity type device region 50N or the second conductivity type device region 50P of the substrate 50 unless specifically discussed. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 55 may further define first nanostructures 64 from the first semiconductor layers 54 and define second nanostructures 66 from the second semiconductor layers 56.

After the nanostructure stack is formed, isolation structures 70 (see FIG. 3B) can formed over the substrate 50 and laterally surrounding the fin structure 62. In some embodiments, the isolation structures 70 may be in contact with sidewalls of the fin structure 62 of the substrate 50. The isolation structures 70 may be shallow trench isolation (STI) structures, suitable isolation structures, combinations of the foregoing, or the like. In some embodiments, the isolation structures 70 may be made of oxide (e.g., silicon oxide), nitride (e.g., silicon nitride), or combinations thereof.

Subsequently, a dummy gate structure can be formed over the substrate 50 and crossing the nanostructure stack. In some embodiments, the dummy gate structure can include a dummy gate dielectric 82 and a dummy gate electrode 84 over the dummy gate dielectric 82. The dummy gate dielectric 82 may be, for example, silicon oxide, silicon nitride, a combination thereof, or the like, and may be deposited or thermally grown according to acceptable techniques. The dummy gate electrode 84 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate electrode 82 and the dummy gate dielectric 84 may be formed by, for example, depositing a dummy dielectric layer and a dummy gate layer over the substrate 50, forming a patterned mask 86 over the dummy gate layer, and then performing an etching process to the dummy dielectric layer and the dummy gate layer by using the patterned mask 86 as etch mask. In some embodiments, the patterned hard mask 86 may be formed of silicon nitride, and the second hard mask 332 may be formed of silicon oxide. In some embodiments, the dummy gate electrode 84 may be deposited by physical vapor deposition (PVD), chemical vapor deposition (CVD), sputter deposition, or other techniques for depositing the selected material. In some embodiments, the dummy gate dielectric 82 may be formed by thermal oxidation.

Spacers 92 can be formed on opposite sidewalls of the dummy gate structure and on opposite sidewalls of the fin structure 62. In some embodiments, the spacers 92 may be formed of silicon oxide, silicon nitride, silicon oxynitride, combinations thereof. In some embodiments, the spacers 92 may be formed by, for example, depositing a spacer layer blanket over the substrate, and then performing an anisotropic etching process to remove horizontal portions of the spacer layer, such that vertical portions of the spacer layer remain on sidewalls of the dummy gate structure and on sidewalls of the fin structure 62. In some embodiments, portions of the spacers 92 on sidewalls of the dummy gate structures can be referred to as gate spacers, and the portions of the spacers 92 on sidewalls of the fin structure 62 can be referred to as fin spacers. In some embodiments, the spacer layer may be deposited using techniques such CVD, ALD, or the like.

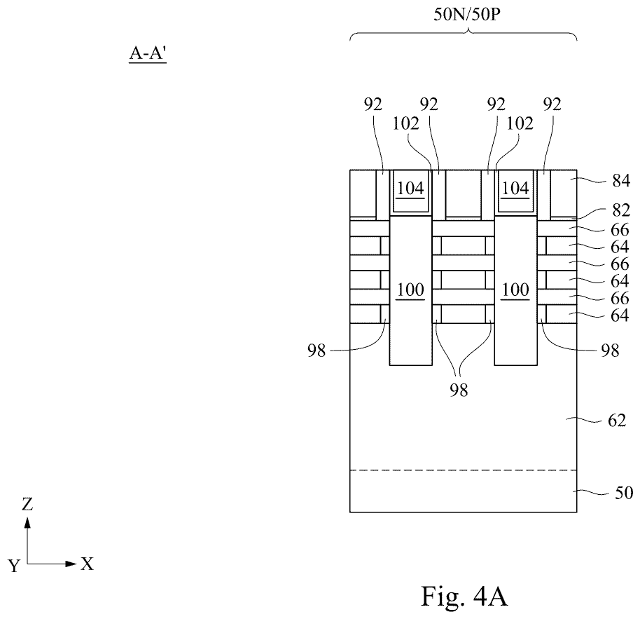

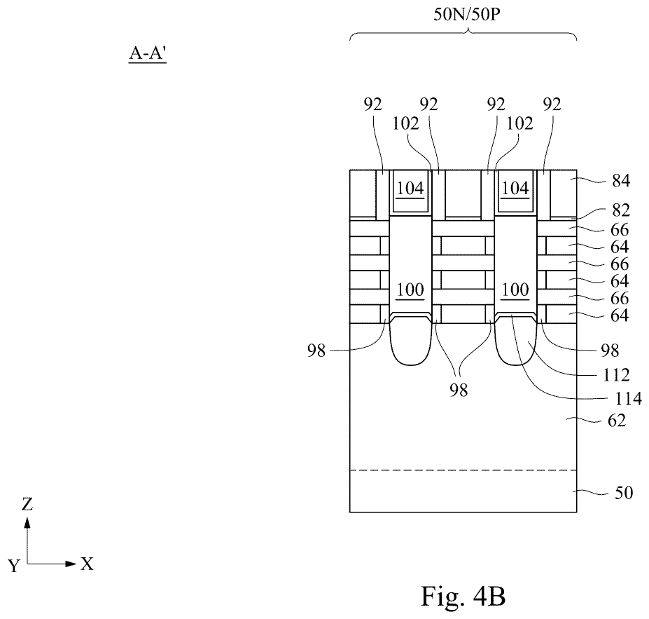

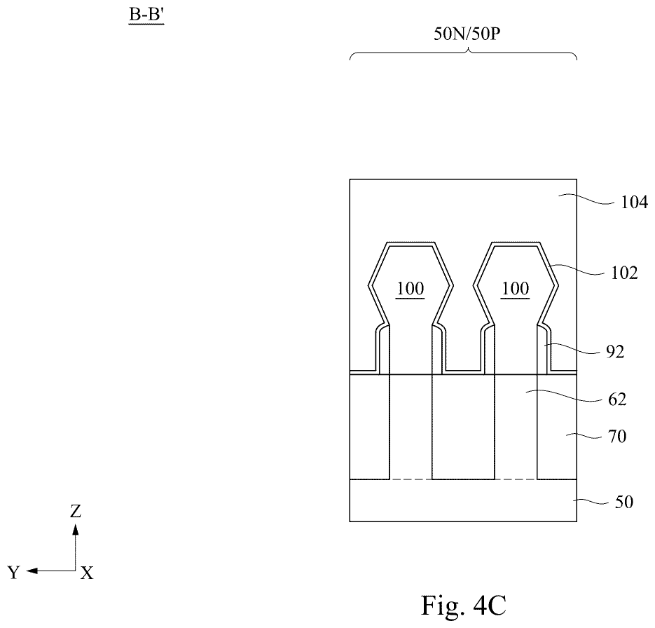

Still referring to FIGS. 3A and 3B, source/drain recesses 96 can be patterned in the fin structures 62 and the nanostructures 64/66 using anisotropic etching processes, such as RIE, NBE, or the like, in accordance with some embodiments. Epitaxial source/drain regions (see FIGS. 4A-4C) can be subsequently formed in the source/drain recesses 96. In some embodiments, the gate spacers 92 and the dummy gates 84 mask portions of the fin structures 62 and the nanostructures 64/66 during the etching processes used to form the source/drain recesses 96. A single etch process or multiple etch processes may be used to etch each layer of the nanostructures 64/66 and/or the fin structures 62. Timed etch processes may be used to stop the etching of the source/drain recesses 96 after the source/drain recesses 96 reach a desired depth. In some embodiments, the fin structures 62 may be etched such that the bottom surfaces of the source/drain recesses 96 are about level with or higher than top surfaces of the STI regions 70. In other embodiments, bottom surfaces of the source/drain recesses 96 are lower than the top surfaces of the STI regions 70.

After the source/drain recesses 96 are formed, inner spacers 98 are formed on opposite ends of each of the nanostructures 64. The inner spacers 98 may be deposited by a conformal deposition process, such as CVD, ALD, or the like. The inner spacer 98 may include a material such as SiN, SiOCN, SiCN, SIOC, although any suitable material, such as low-dielectric constant (low-k) materials having a k-value less than about 3.5, may be utilized. The inner spacers 98 can be formed by, for example, performing an etching process to laterally etch the nanostructures 64 to form sidewall recesses 97. In some embodiments, the sidewalls of the nanostructures 64 may be etched using isotropic etching processes, such as wet etching or the like. In some embodiments where the nanostructures 64 include, e.g., SiGe, and the nanostructures 66 include, e.g., Si, an etch process with tetramethylammonium hydroxide (TMAH), ammonium hydroxide (NH₄OH), or the like may be used to etch sidewalls of the nanostructures 64. Then, inner spacers 98 are formed in the sidewall recesses 97 on opposite ends of each of the nanostructures 64. In some embodiments, the inner spacers 98 may be formed by, for example, depositing a dielectric material blanket over the substrate 50 and filling the sidewall recesses and the gap, and then performing an anisotropic etching to remove portions of the dielectric material outside the sidewall recesses and the gap, leaving the remaining portions of the dielectric material in the sidewall recesses 97 as the inner spacers 98.

Reference is made to FIGS. 4A and 4C. Source/drain regions 100 can be formed in the source/drain recesses 96 (see FIGS. 3A and 3B) of the first conductivity type device region 50N and in the source/drain recesses 96 of the second conductivity type device region 50P, in accordance with some embodiments. The source/drain regions 100 in the first conductivity type device region 50N may be referred to as n-type source/drain regions 100, and the source/drain regions 100 in the second conductivity type device region 50P may be referred to as p-type source/drain regions 100. The n-type source/drain regions 100 may be formed before, after, or simultaneously with the formation of the p-type source/drain regions 100. The source/drain regions 100 may be formed by an epitaxy process, such as such as vapor phase epitaxy (VPE), molecular beam epitaxy (MBE), or the like. The source/drain regions 100 may be in-situ doped, and/or may be implanted, with an n-type or p-type dopant.

In some embodiments, the source/drain regions 100 exert stress on channel regions of the nanostructures 66 within the first conductivity type device region 50N and/or within the second conductivity type device region 50P, thereby improving performance. The source/drain regions 100 can be formed in the source/drain recesses 96 such that each dummy gate electrode 84 of the second conductivity type device region 50P is disposed between respective neighboring pairs of the source/drain regions 100. In some embodiments, the gate spacers 92 can be used to separate the source/drain regions 100 from the dummy gates 84, and the inner spacers 98 can be used to separate the source/drain regions 100 from the nanostructures 66 by an appropriate lateral distance such that the source/drain regions 100 do not short out with subsequently formed gates of the resulting nanostructure-FETs.

The source/drain regions 100 may be implanted with dopants to form source/drain regions, followed by an annealing process. The source/drain regions may have an impurity concentration of between about 1×10¹⁹ atoms/cm³ and about 1×10²² atoms/cm³. In some embodiments, the source/drain regions 100 may be in situ doped during growth. After the implants of the first conductivity type device region 50N and the second conductivity type device region 50P, an annealing process may be performed to repair implant damage and to activate the p-type and/or n-type impurities that were implanted.

For example, the source/drain regions 100 in the first conductivity type device region 50N may be formed by masking the second conductivity type device region 50P. Then, n-type source/drain regions 100 can be epitaxially grown in the source/drain recesses 96 in the first conductivity type device region 50N. The n-type source/drain regions 100 may include any acceptable material appropriate for n-type nanostructure-FETs. For example, if the nanostructures 66 are silicon, the n-type source/drain regions 100 may include materials exerting a tensile strain on the nanostructures 66, such as silicon, silicon carbide, phosphorous doped silicon carbide, silicon phosphide, or the like. An n-type impurity implant can be performed on the n-type source/drain regions 100 in the second conductivity type device region 50P. The n-type impurities may include phosphorus, arsenic, antimony, the like, or combinations thereof.

The source/drain regions 100 in the second conductivity type device region 50P may be formed by masking the first conductivity type device region 50N. Then, p-type source/drain regions 100 can be epitaxially grown in the source/drain recesses 96 in the second conductivity type device region 50P. The p-type source/drain regions 100 may include any acceptable material appropriate for p-type nanostructure-FETs. For example, if the nanostructures 66 are silicon, the p-type source/drain regions 100 may include materials exerting a compressive strain on the nanostructures 66, such as silicon germanium, boron doped silicon germanium, germanium, germanium tin, or the like. A p-type impurity implant may be performed on the p-type source/drain regions 100 in the second conductivity type device region 50P. The p-type impurities may include boron, boron fluoride, indium, the like, or combinations thereof.

FIG. 4B illustrates a semiconductor structure corresponding to FIG. 4A in accordance with some embodiments of the present disclosure. While FIG. 4B illustrates an embodiment of semiconductor structure with different structural configurations with additional semiconductive layer 112 and dielectric layer 114 than in FIG. 4A, the present disclosure may repeat reference numerals and/or letters in the various examples. This repetition is for simplicity and clarity and does not dictate a relationship between the various embodiments and/or configurations discussed.

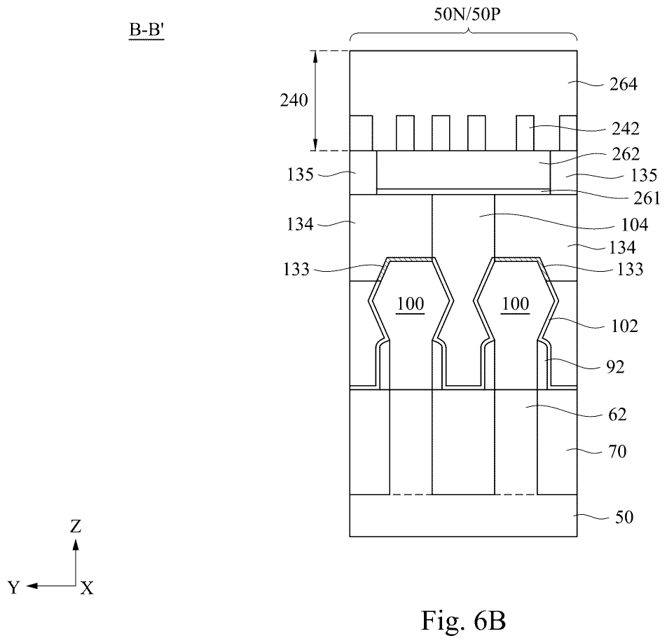

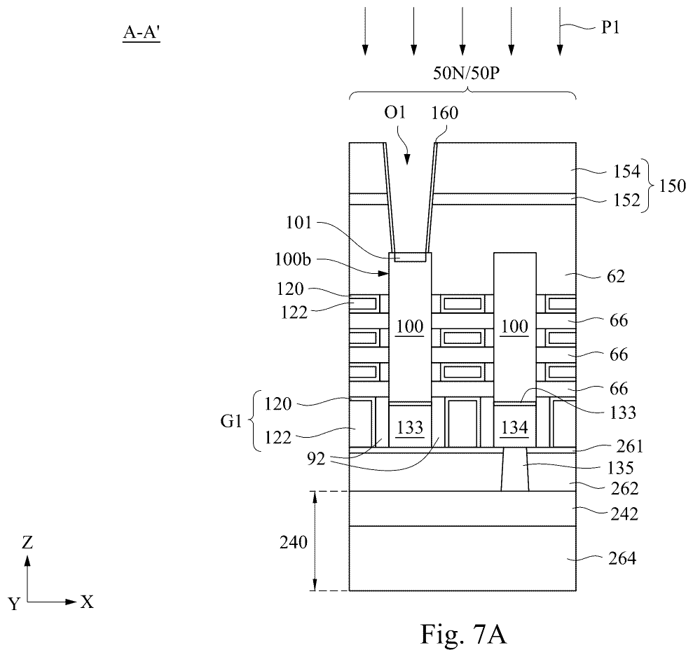

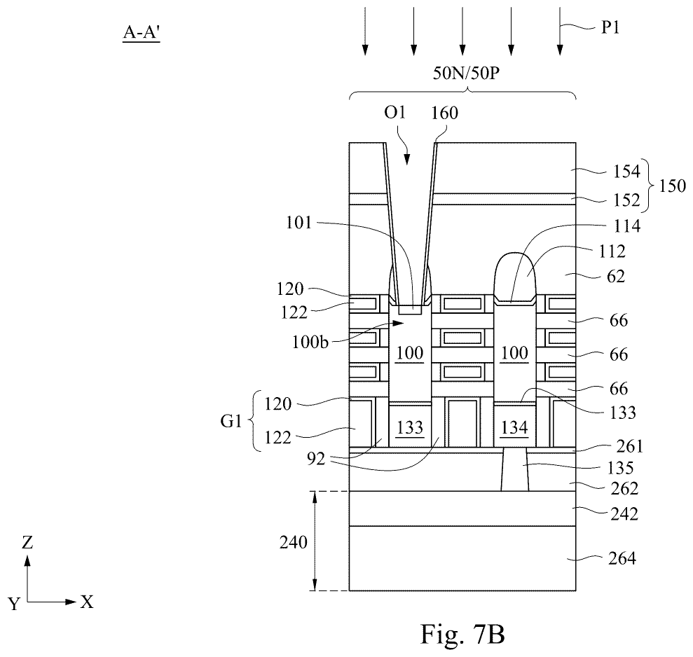

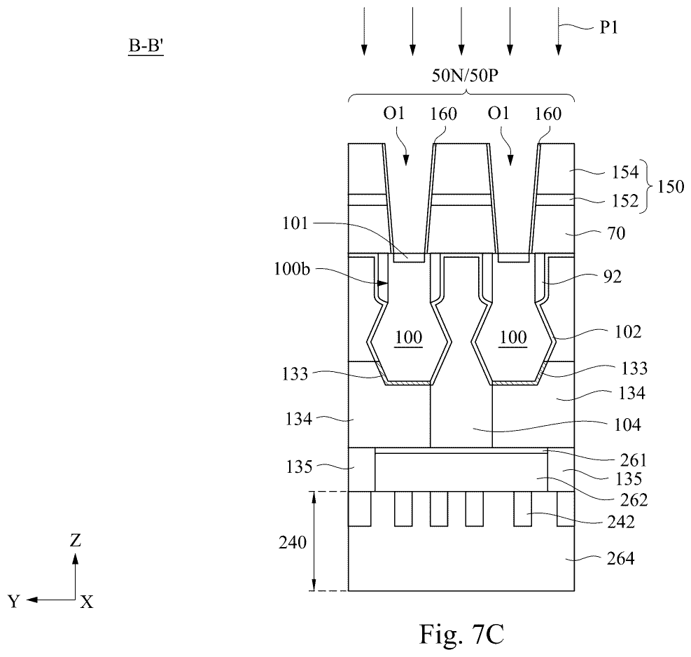

Specifically, before forming the source/drain region 100, the semiconductive layer 112 and the dielectric layer 114 can be sequentially deposited at the bottom of the source/drain recess 96 (see FIG. 3A). The semiconductive layer 112 can be formed using various deposition techniques, such as chemical vapor deposition (CVD), which offers uniformity and scalability; molecular beam epitaxy (MBE), which provides control over thickness and composition; or physical vapor deposition (PVD), such as sputtering, which is effective for thin film formation. In some embodiments, the semiconductive layer 112 can be made of undoped semiconductor material. In some embodiments, the semiconductive layer 112 can include undoped crystalline or amorphous silicon (Si), silicon-germanium (SiGe), silicon carbide (SiC), the like, or combinations thereof. The semiconductive layer 112 can serve as an etch stop layer during subsequent processing steps, such as when forming the opening O1 (see FIG. 7A) from the back side of the semiconductor structure, to prevent over-etching into the source/drain region 100 or other underlying layers, and thus the semiconductive layer 112 can be interchangeable referred to as an etch stop layer. In some embodiments, the semiconductive layer 112 can be interchangeable referred to as an epitaxial layer.

As shown in FIG. 4B, above the semiconductive layer 112, the dielectric layer 114 can be deposited using, such as, thermal oxidation, atomic layer deposition (ALD), plasma-enhanced chemical vapor deposition (PECVD), or the like. In some embodiments, the dielectric layer 114 can be made of silicon dioxide (SiO₂), silicon nitride (Si₃N₄), silicon oxynitride (SiON), high-k materials, such as hafnium oxide (HfO₂) or aluminum oxide (Al₂O₃), the like, or combinations thereof. The dielectric layer 114 can isolate the source/drain region 100 from back-side components of the semiconductor structure, providing electrical insulation and preventing interference or leakage currents. In some embodiments, the dielectric layer 114 can be interchangeable referred to as an isolation layer or a flexible bottom isolation.

A contact etch stop layer (CESL) 102 can be formed covering the source/drain regions 100. Afterwards, an interlayer dielectric (ILD) layer 104 can be formed over the CESL 102. Then, a planarization process, such as CMP, is performed to remove excess materials of the CESL 102 and the ILD layer 104 until the dummy gate structure is exposed. In some embodiments, the patterned masks 86 are removed during the planarization process. In some embodiments, the CESL 102 may be a dielectric layer including silicon nitride, silicon oxynitride or other suitable materials. In some embodiments, the ILD layer 104 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes(BCB), or polyimide. The CESL 102 and the ILD layer 104 can be formed using, for example, CVD, ALD or other suitable techniques.

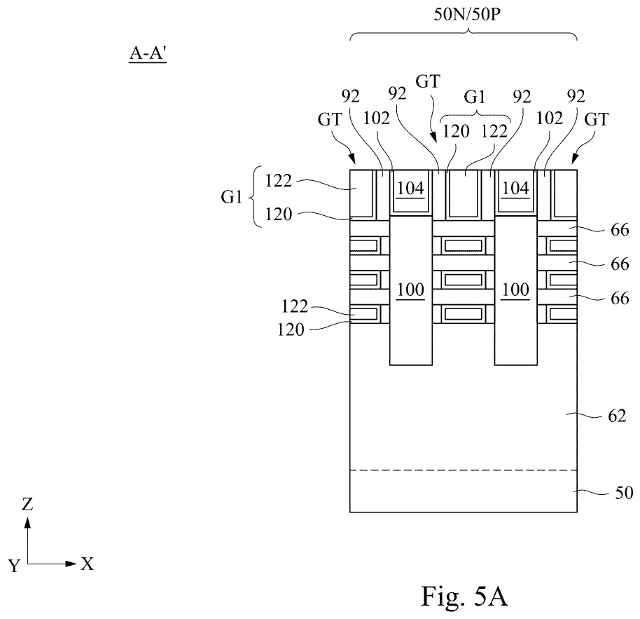

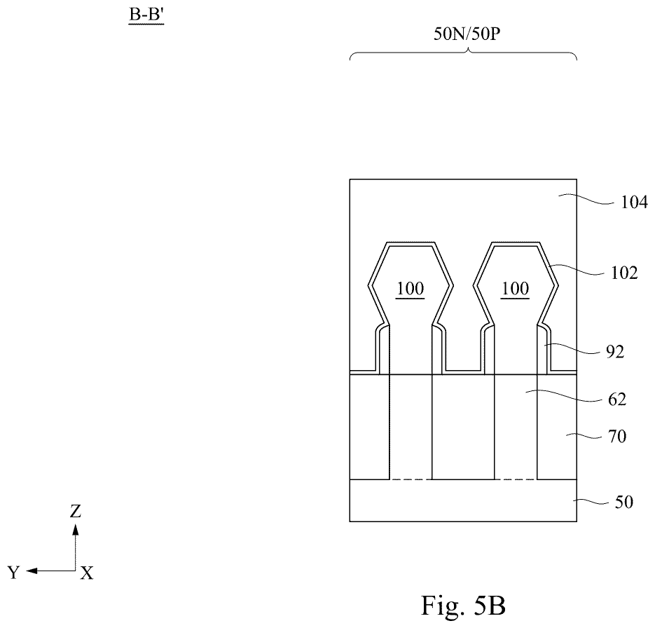

Reference is made to FIGS. 5A and 5B. The dummy gate structure including the dummy gate dielectric 82 (see FIGS. 4A and 4B) and the dummy gate electrode 84 (see FIGS. 4A and 4B) can be removed to form gate trench GT between the gate spacers 92. Then, an etching process is performed to remove the nanostructures 64 (see FIGS. 4A and 4B), such that the nanostructures 66 can be suspended over the substrate 50.

Subsequently, a gate dielectric layer 120 can be formed on exposed surfaces of the nanostructures 66. Then, a gate electrode layer 122 can be formed in the gate trench GT and over the gate dielectric layer 120. Accordingly, metal gate structure G1 can be formed. The metal gate structure G1 may wrap around the respective nanostructure 66. In some embodiments, the metal gate structure G1 may include the gate dielectric layer 120 and the gate electrode layer 122 over the gate dielectric layer 120.

In some embodiments, the gate dielectric layer 120 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the gate electrode layer 122 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

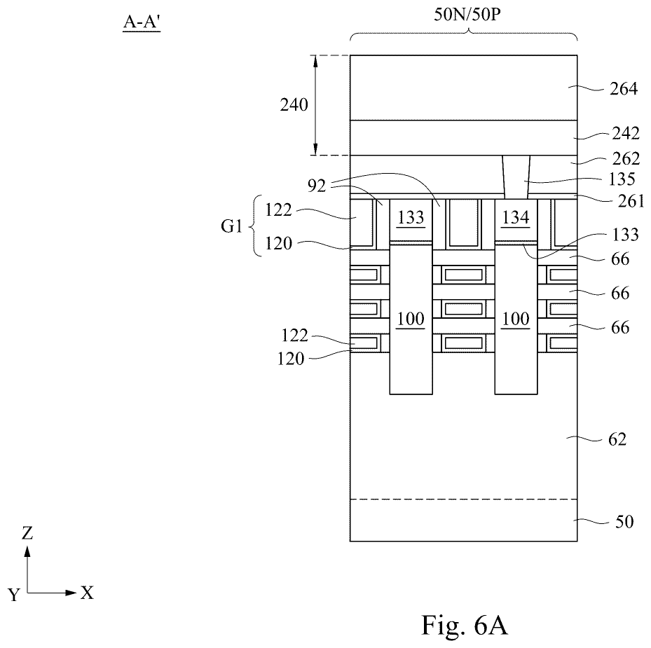

Reference is made to FIGS. 6A and 6B. Source/drain contacts 134 can be formed in the CESL 102 and the ILD layer 104 and over the source/drain regions 100. Specifically, a removal process can include defining the regions using photolithography, where a mask is used to pattern the regions on the dielectric material (e.g., ILD layer 104 and ILD layer 104) that needs to be cut or shaped. After the removal areas are defined, an etching process can remove the unwanted dielectric material, thereby shaping the dielectric isolation around the metal contacts. Following the shaping of dielectric isolation, the exposed areas within the defined regions can be prepared for metal deposition. A metal such as Cu, Co, Ru, Pt, Al, W, Ti, TaN, TiN, molybdenum (Mo), ruthenium (Ru), iridium (Ir), rhodium (Rh), or any combinations thereof, known for good conductivity, can be deposited over the semiconductor structure. The deposition can be performed using chemical vapor deposition (CVD), physical vapor deposition (PVD), or electrochemical plating, depending on the material and desired properties of the source/drain contacts 134. Once the metal is deposited, a removal process, such as chemical mechanical planarization (CMP) can be employed on the deposited metal. The result of the CMP process can be a series of metal-filled trenches that form the source/drain contacts 134.

In some embodiments, a front-side silicide layer 133 can be formed over the epitaxial source/drain region 100. In some embodiments, a metal silicidation process can be performed on the epitaxial source/drain region 100 to form the front-side silicide layer 133. The metal silicidation process is to make a reaction between metal and silicon (or polycrystalline silicon). In some embodiments, a metal layer can be formed on the epitaxial source/drain region 100. Subsequently, regarding the metal silicidation process, a first rapid thermal annealing (RTA) process may be performed in, for example, Ar, He, N₂ or other inert atmosphere at a first temperature, such as lower than 200~300° C., to convert the deposited metal layer into metal silicide. This is followed by an etching process to remove the unreacted metal layer from. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400~500° C., thereby forming the front-side silicide layer 133 with low resistance. In some embodiments, the front-side silicide layer 133 may include titanium silicide (TiSi), nickel silicide (NiSi), cobalt silicide (CoSi), Ni—Pt, or combinations thereof.

Subsequently, a etch stop layer (ESL) 261 can be deposited over the CESL 102 and the ILD layer 104, and then an ILD layer 262 can be deposited over the ESL 261. Subsequently, a metal via 135 can be formed in the ILD layer 262 and land on the source/drain contact 134. The metal via 135 may include a metal-containing material such as titanium nitride, titanium oxide, tungsten, cobalt, ruthenium, aluminum, copper, combinations thereof, multi-layers thereof, or the like. The ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. The ESL 261 may be formed of a dielectric material having a high etching selectivity from the etching of the ILD layer 262, such as silicon nitride, silicon oxide, silicon oxynitride, a combination thereof, or the like, which may be formed using any suitable deposition process, such as CVD, ALD, or the like.

Subsequently, a front-side interconnect structure 240 can be formed over the metal vias 135. The front-side interconnect structure 240 can include a plurality of metallization layers with a plurality of metallization vias or interconnects. Other embodiments may contain more or fewer metallization layers and corresponding more or fewer number of vias. The front-side interconnect structure 240 may include front-side inter-metal dielectric (IMD) layer 264 and at least one front-side metallization layer 242 formed in the IMD layer 264. In some embodiments, materials of the front-side metallization layer 242 may include Cu, Co, Ru, Pt, Al, W, Ti, TaN, TiN, molybdenum (Mo), ruthenium (Ru), iridium (Ir), rhodium (Rh), or any combinations thereof. In some embodiments, the IMD layer 264 may be formed of an oxide such as phospho-silicate glass (PSG), boro-Silicate Glass (BSG), boron-doped phospho-silicate glass (BPSG), tetra ethyl ortho silicate (TEOS) oxide, or the like.

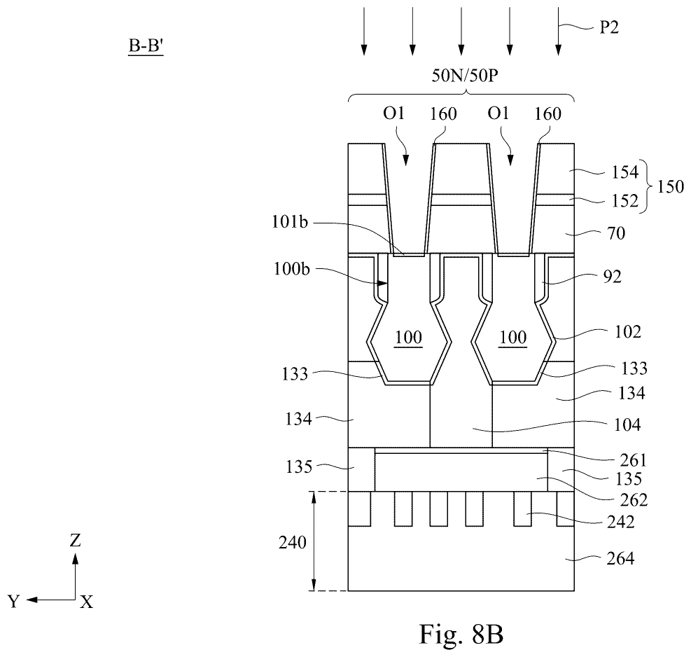

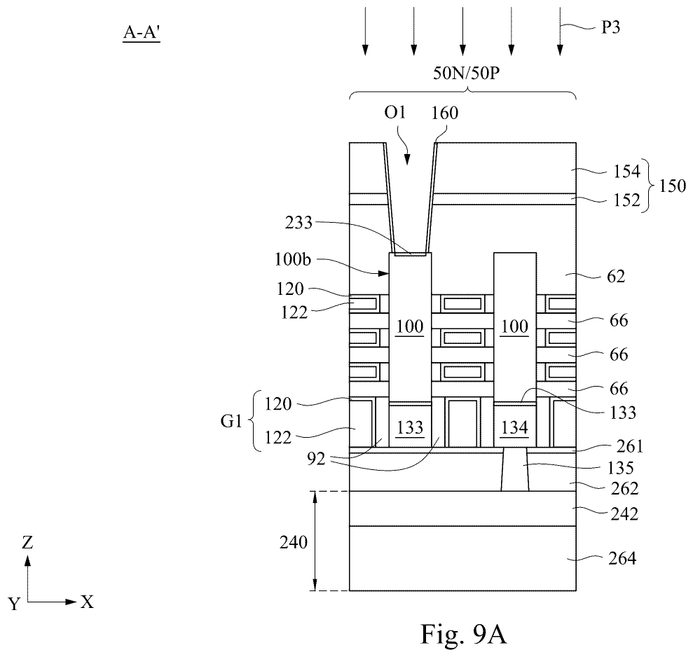

FIGS. 7A-9B and 11A-11F illustrate backside processing steps in semiconductor devices. Backside implantation process P1 (see FIGS. 7A-7C and 11B) can introduce high dopant concentrations (>1×10²¹ atoms/cm³) into the source/drain regions from the back-side of the source/drain regions, creating an amorphous backside implanted region 101. To activate dopants without affecting front-side components (e.g., silicide layer 133), nanosecond laser annealing (NSA) process P2 (see FIGS. 8A, 8B, and 11C) can be applied. The NSA process P2 can use lasers with wavelengths shorter than 400 nm, which can pass through dielectric layers without heating them but are absorbed by the semiconductor material. This causes localized heating within about 10 nm of the surface, activating dopants and recrystallizing part of the amorphous region (e.g., backside implanted region 101) into crystalline region (e.g., crystalline region 101a), while thinning the remaining amorphous region (e.g., amorphous region 101b). Subsequently, a metal silicidation process (see FIGS. 9A, 9B, and 11F) then can form a backside silicide layer 233 in the thin amorphous region 101b. Then, backside contacts can be formed over the backside silicide layer 233. This backside processing can enhance electrical performance by improving dopant activation and reducing contact resistance while preserving the integrity of front-side components.

Reference is made to FIGS. 7A, 7C, 11A and 11B. The structures of FIGS. 6A and 6B can be flipped upside down, and the substrate 50 can be removed. The substrate 50 may be removed in a plurality of process operations, for example, CMP, HNA, and/or TMAH etching from the back-side of the substrate 50, which stops at the isolation region 70 (see FIG. 7C) or the fin structure 62 (see FIG. 7A). After the removal process, the isolation region 70 and/or the fin structures 62 can be exposed as shown in FIGS. 7A and 7C. Subsequently, a dielectric structure 150 can be formed over the isolation region 70 and/or the fin structures 62. In some embodiments, the dielectric structure 150 can include at least one dielectric layer (e.g., dielectric layers 152 and 154 shown in FIGS. 7A and 7C). In some embodiments, the dielectric layer 154 can be made of a different material than the dielectric layer 152. In some embodiments, the dielectric layer 152/154 may be made of dielectric material, such as SiO₂, Si₃N₄, SiON, SiOC, SiOCN base dielectric material, or combinations thereof. In some embodiments, the dielectric layer 152/154 may be made of a material having a dielectric constant greater than about 9 (e.g., high dielectric constant (high-k) material). For example, the dielectric layer 152/154 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. By way of example but not limiting the present disclosure, the dielectric layer 152 can be made of nitride (e.g., SiN), and the dielectric layer 154 can be made of oxide (e.g., SiO₂).

The dielectric structure 150 and the fin structures 62 can be patterned to form an opening O1 in the isolation structure 250 and the fin structures 62. In some embodiments, the opening O1 can expose the underlying source/drain region 100. In some embodiments, the dielectric structure 150 and the fin structures 62 can be patterned, for example, forming a mask layer (not shown) over the dielectric structure 150 and exposing unwanted portion of the dielectric structure 150, performing an etching process to remove the unwanted portion of the dielectric structure 150 until top surface the source/drain region 100 is exposed, and then removing the mask layer once the etching process is complete. In some embodiments, a portion of the second source/drain region 100 may also be removed during the etching process. In some embodiments, the etching process may include an anisotropic etching process, such as a plasma dry etch.

A spacer layer 160 can be deposited over the dielectric structure 150 and line the opening O1 in the isolation structure 150. In greater detail, the spacer layer 160 may line the opposite sidewalls and bottom of the opening O1. In some embodiments, the spacer layer 160 may be made of a dielectric material, such as silicon nitride (SiN), silicon oxynitride (SiON), and other carbon-doped low-k dielectrics, such as SiOCN material. The spacer layer 160 may be formed using suitable deposition process, such as physical vapor deposition (PVD), chemical vapor deposition (CVD), atomic layer deposition (ALD), or other suitable deposition process. Subsequently, an etching process can be performed to remove portions of the spacer layer 160. In some embodiments, the etching process may be a directional etching process, such as a plasma dry etching, in which the etchants (e.g., particles, ions, plasma) may be directed along a certain direction (e.g., the vertical direction). Accordingly, the etching process may substantially remove the horizontal portions of the spacer layers 160, while leaving the vertical portions of the spacer layer 160 remaining over the dielectric structure 150 once the etching process is complete.

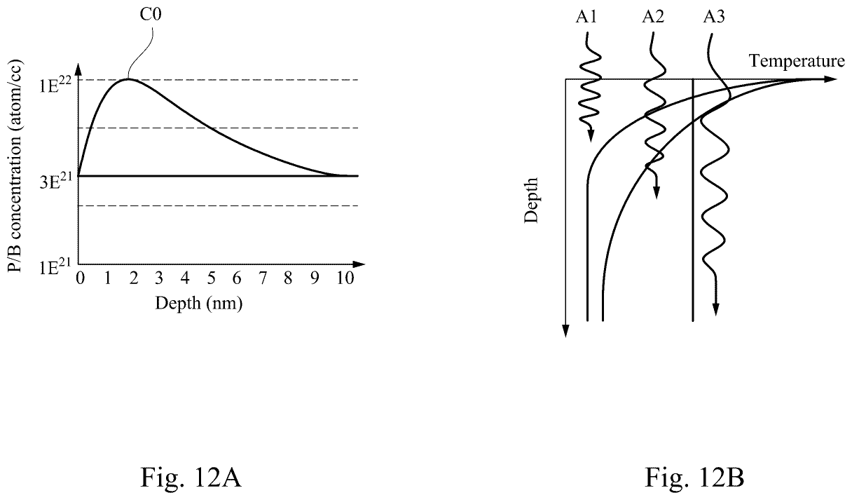

A back-side implantation process P1 can be performed to modify the back-side of the source/drain region 100, converting part of the crystalline source/drain region 100 (as shown in FIG. 11A), such as the back-side portion 100b (depicted in FIGS. 7A and 7C), into a back-side implanted region 101 (see FIG. 11B). In the backside implanted region 101, the dopant concentration can reach levels above approximately 1×10²¹ atoms per cubic centimeter. For example, the dopant concentration can be in a range from approximately 1×10²¹ to 5×10²² atoms per cubic centimeter, such as from approximately 1×10²¹, 5×10²¹, 1×10²², 2×10²², 3×10²², 4×10²², or 5×10²² atoms per cubic centimeter. The Gaussian dopant profile observed in FIG. 12A can result from the statistical nature of ion implantation. When dopants are implanted into the source/drain region 100 from the backside, they can penetrate the lattice to varying depths due to differences in energy and scattering events, leading to a peak concentration at a specific depth below the surface, with the concentration decreasing symmetrically on either side of this peak. Comparatively, the dopant concentration in the backside implanted region 101 can be higher than in other areas of the source/drain region 100. The high dopant concentration can increase the carrier density within the silicon lattice, providing more free electrons in n-type regions or holes in p-type regions, enhancing the electrical conductivity of the region.

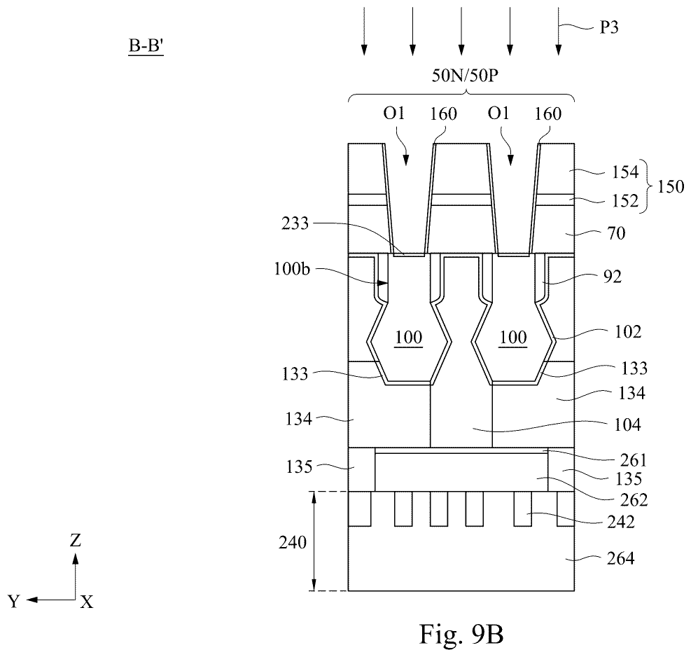

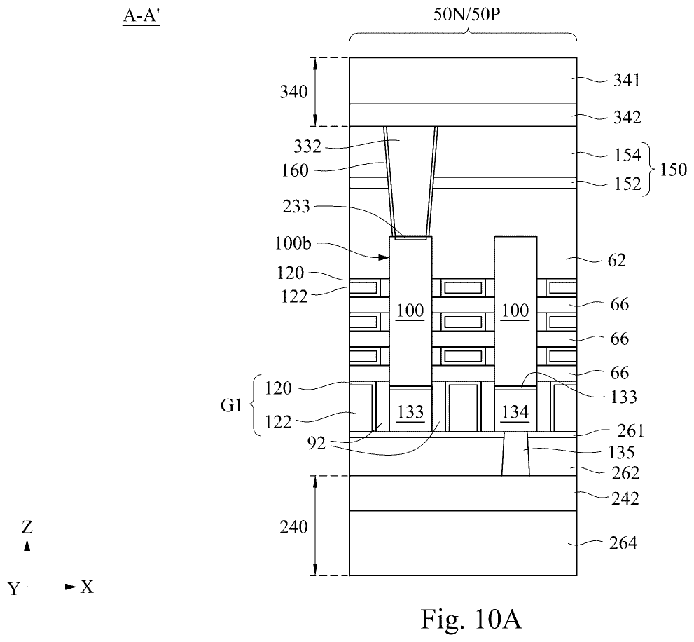

During the back-side implantation process P1, implantation damage may cause the formation of an amorphous region within the back-side implanted region 101. This amorphous region can then be converted into metal silicide, such as the back-side silicide layer 233 illustrated in FIGS. 10A, 10B, and 11F. The back-side implantation process P1 can form an amorphous region in the back-side portion 100b of the source/drain regions 100 because the high-energy ion bombardment during implantation disrupts the regular crystal lattice of the source/drain region 100. This damage can be enough to break the bonds within the crystalline structure, transforming it into a disordered, amorphous state. The back-side implantation process P1 can intentionally create this amorphous region because it facilitates subsequent steps, such as the formation of a metal silicide layer, which improves electrical contact properties and reduces resistivity. The amorphous state is more chemically reactive, allowing for better interaction with the metal during silicidation, which is crucial for forming an effective electrical connection.

The metal silicide (e.g., back-side silicide layer 233 illustrated in FIGS. 10A, 10B, and 11F) may tend to form in the amorphous region of the source/drain region 100 because the amorphous structure can be more chemically reactive compared to the crystalline structure. The disordered arrangement of atoms in the amorphous region can provide a higher density of unsatisfied chemical bonds, which may promote the reaction between the implanted metal and the silicon during the silicidation process. In contrast, the crystalline structure has a well-ordered lattice with fewer available reactive sites, making it less favorable for silicide formation. Therefore, the amorphous region can serves as a template for the formation of metal silicide, ensuring better uniformity and lower contact resistance for reliable electrical performance.

The back-side implantation process P1 can enhance the electrical characteristics of the source/drain region by altering its physical structure. Specifically, the transformation from a crystalline to an amorphous state can allow for subsequent processing steps, such as silicidation, to be more effective. The amorphous region that forms as a result of implantation damage serves as a precursor for creating metal silicide, which can lower the contact resistivity between the metal and the semiconductor.

However, if an annealing process is used to form a contact on the back-side of the source/drain region 100, it may negatively impact the front-side components (e.g., front-side silicide layer 133, source/drain contact 134, metal via 135). The annealing process may include high temperatures, which can cause degradation or unwanted diffusion of these front-side components. Since these components are sensitive to heat, excessive temperatures can lead to issues such as metal atom migration, silicide breakdown, or even the melting of metal contacts. This may compromise the integrity and electrical performance of the front-side components, affecting device reliability. To address this, alternative methods, such as localized laser annealing (e.g., nanosecond laser annealing (NSA)) can be introduced, as they can effectively activate dopants in the back-side implanted region while minimizing thermal exposure to the front-side.

FIG. 7B illustrates a semiconductor structure corresponding to FIG. 7A in accordance with some embodiments of the present disclosure. While FIG. 7B illustrates an embodiment of semiconductor structure with different structural configurations with additional semiconductive layer 112 and dielectric layer 114 than in FIG. 7A, the present disclosure may repeat reference numerals and/or letters in the various examples. This repetition is for simplicity and clarity and does not dictate a relationship between the various embodiments and/or configurations discussed.

Specifically, the structure illustrated in FIG. 7B can undergo the same processes as those preceding FIG. 7A and will subsequently undergo the processes described in FIGS. 8A-10B. Similar to the structure illustrated in FIG. 4B, the structure in FIG. 7B can include the additional semiconductive layer 112 and dielectric layer 114 compared to FIG. 7A. The semiconductive layer 112 can serve as an etch stop layer during subsequent fabrication steps. For instance, when forming the opening O1 from the back side of the semiconductor structure, the semiconductive layer 112 can prevent over-etching into the source/drain region 100 or other underlying layers. After the opening O1 has been formed, the process can include etching through the dielectric layer 114 to expose the source/drain region 100, enabling further device formation steps.

Reference is made to FIGS. 8A, 8B, and 11C. A nanosecond laser annealing (NSA) process P2 can be performed to the backside implanted region 101 from the backside of the source/drain region 100. The NSA process P2 can enhance dopant activation within the backside implanted region 101. This enhancement can result in the formation of a crystalline region 101a inside the backside implanted region 101, as depicted in FIG. 11C. The NSA process P1 can include irradiating the backside implanted region 101 with high-energy laser pulses of nanosecond duration. These rapid pulses can provide localized heating that is sufficient to activate the dopants introduced during the backside implantation process P1 without causing thermal diffusion to other parts of the device.

The activation of dopants occurs because the NSA process P2 can provide enough energy for the dopant atoms to move into substitutional positions within the silicon lattice, making them electrically active. This activation can boost the electrical conductivity of the crystalline region 101a. The rapid heating and cooling inherent in the NSA process P2 also can initiate recrystallization of the amorphous silicon created during implantation, and the NSA process P2 can be a solid phase epitaxial regrowth (SPER) process. In some embodiments, after the NSA process P2 is complete, locations like position C0 shown in FIG. 12A, where the dopant concentration is highest, can be located within the crystalline region 101a. The crystalline region 101a that forms within the backside implanted region 101 will not participate in metal silicide formation during later processing steps, as indicated in FIGS. 10A, 10B, and 11F. This is because the recrystallized silicon does not readily react with the metal during the silicidation process, preserving the integrity of the source/drain regions 100. The high dopant concentration within the crystalline region can enhances carrier mobility and reduces resistance, thereby improving the electrical performance of the device.

As a result of the NSA process P2, the original amorphous region formed during the implantation shrinks, becoming a thinner amorphous region 101b. The thickness of the amorphous region can reduce from its initial thickness T1 (see FIG. 11B) to a smaller thickness T2 (FIG. 11C). For example, if the initial thickness T1 is approximately 10 nm, the reduced thickness T2 could be approximately 1 nm. This means that the thickness T2 can be less than half of the thickness T1, potentially being one-half, one-third, or even as little as one-tenth of the thickness T1. The reduction in thickness can minimize the area where metal silicide (e.g., back-side silicide layer 233 shown in 9A, 9B, and 11F) can form in subsequent processing steps. By reducing the thickness of the amorphous region 101b to the thickness T2, the area available for metal silicide formation can be minimized. The metal silicide may tend to form preferentially in amorphous silicon regions due to their higher chemical reactivity compared to crystalline silicon. A thinner amorphous region 101b can confine the silicide formation to a smaller area, which can reduce contact resistance at the metal-semiconductor interface because the silicide layer can be thinner and more uniform. In some embodiments, the thickness T2 of the amorphous region 101b is thinner than the thickness of the crystalline region 101a of the backside implanted region 101.

In some embodiments, the NSA process P2 can be applied to both n-type and p-type source/drain regions either simultaneously or separately. When annealed simultaneously, the NSA process P2 can streamline manufacturing by reducing the number of steps required. Alternatively, annealing them separately can allow for optimization of the annealing parameters specific to each dopant type, potentially enhancing device performance by tailoring the activation levels and minimizing unwanted diffusion.

Thus, after the NSA process P2, the crystalline region 101a can possess a high concentration of activated dopants due to both the initial implantation and the enhanced activation from the laser annealing. The crystalline region 101a can contribute to improved electrical conductivity without the risk of unwanted silicide formation. Simultaneously, the amorphous region 101b can be kept thin, effectively controlling the extent of metal silicide formation in subsequent steps. This balance can ensure that the device can achieve optimal electrical characteristics, such as low contact resistance and high carrier mobility, while maintaining structural integrity and reliability.

In some embodiments, the NSA process P2 can employ a laser with a wavelength shorter than approximately 400 nanometers (nm), selecting from wavelengths such as about 400, 380, 350, 320, 300, 250, 220, 200, 180, 150, 120, or 100 nm. The wavelength of the laser can influence the depth to which the semiconductor material is heated during the NSA process P2. Specifically, lasers with wavelengths shorter than 400 nm can be absorbed more readily by semiconductor materials like silicon, resulting in heating confined to a shallow region near the surface, within approximately 10 nanometers (e.g., about 10, 8, 6, 4, or 2 nm).

This selective heating may occur due to the differing optical properties of dielectric materials and semiconductors. Dielectric materials, such as the dielectric structure 150 depicted in FIGS. 8A and 8B, can be transparent to the laser light (or ultraviolet light) with wavelengths less than 400 nm. Materials like silicon dioxide (SiO2) or silicon nitride (Si3N4), used as dielectrics, have wide band gaps that do not absorb photons in this wavelength range. Consequently, the laser light can pass through these dielectric layers without absorption, meaning the dielectric material does not experience a temperature increase during the NSA process P2. When the laser reaches the semiconductor material, such as the source/drain region 100 shown in FIGS. 8A and 8B, the situation can change. The semiconductive material, such as silicon, can have smaller band gap and higher absorption coefficient for laser light. Photons with wavelengths shorter than 400 nm can have sufficient energy to be absorbed by silicon, exciting electrons across the band gap and generating heat within the semiconductive material, leading to a rapid rise in temperature in the semiconductor material within the penetration depth of the laser.

The heating effect can be localized to a shallow depth because the absorption coefficient of silicon increases with decreasing wavelength. Shorter wavelengths can be absorbed more strongly and thus penetrate less deeply. For example, at a wavelength of 400 nm, the absorption depth in silicon can be about 10 nm, whereas at 200 nm, the absorption depth can reduce to about 5 nm, allowing control over the heating depth by selecting the appropriate laser wavelength. By adjusting the wavelength, the NSA process P2 can target specific regions within the semiconductor material for annealing. For example, FIG. 12A shows that different laser wavelengths result in different heating depths in the semiconductor material. As depicted in FIG. 12B, a laser wavelength of less than 400 nm, indicated as A1, can result in heating to a depth of less than 10 nm, while wavelengths greater than 600 nm, indicated as A2, can penetrate to a depth of approximately 1 μm, and wavelengths above 1,000 nm, indicated as A 3, can heat to a depth greater than 10 μm. Among these wavelengths, a laser wavelength of less than 400 nm can achieve localized heating in the semiconductive material. This is because shorter wavelengths can concentrate the energy near the surface, allowing for controlled activation of dopants without affecting deeper layers or causing damage to front-side components. In some embodiments, the NSA process P2 may also use other wavelengths to heat the semiconductive material, with the wavelength depending on the depth of the implant process within the semiconductive material.

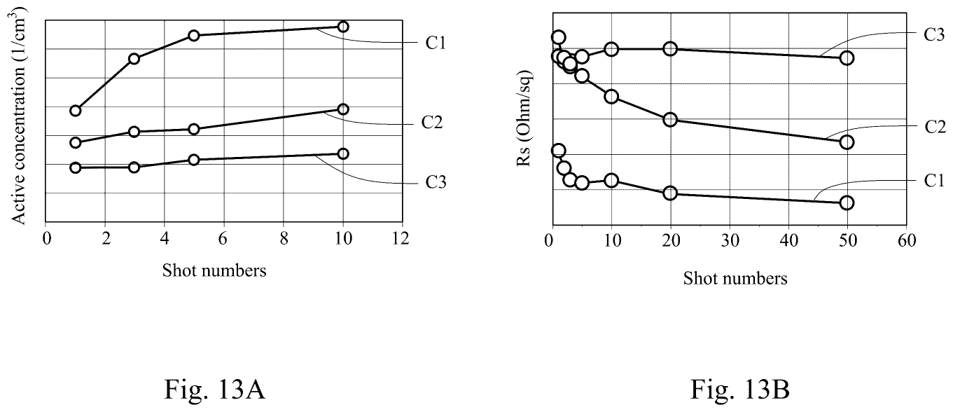

FIGS. 13A and 13B demonstrate that with a high number of laser shots (e.g., greater than approximately 8, such as 8, 10, 20, 30, 40, 50, 60, 70, 80, 90, or 100), using medium energy density (ED) in the NSA process P2 can achieve both improved active dopant concentration and improved sheet resistance (Rs), where Rs represents the contact resistance measured after metal silicide formation (see FIGS. 10A, 10B, and 11F). In the graphs, FIG. 13A shows how the sheet resistance (Rs) decreases with increasing shot numbers, particularly when medium or high energy densities are used on the n-type/p-type source/drain region. High energy density (ED) denoted as C1 can result in the fastest reduction in Rs, but medium ED denoted as C2 also can show improvement, as the number of shots increases. FIG. 13B shows the active dopant concentration in the backside implanted region 101, which also improves with a higher number of shots, and medium ED can demonstrates a good balance of achieving high dopant activation while avoiding excessive temperatures.

In some embodiments, low energy density denoted as C3 can be defined as less than approximately 0.5 J/cm², high energy density can be defined as greater than approximately 1.3 J/cm², and medium energy density can be defined as between about 0.5 J/cm² and 1.3 J/cm², such as about 0.5, 0.6, 0.7, 0.8, 0.9, 1.0, 1.1, 1.2, or 1.3 J/cm². While high energy density (e.g., greater than about 1.3 J/cm²) can be effective in reducing Rs and activating dopants, it may also generate excessively high temperatures that can affect front-side components of the source/drain region 100 (e.g., front-side silicide layer 133, source/drain contact 134, metal via 135). Excessive temperatures can lead to issues such as thermal degradation, unwanted diffusion, or even melting of these sensitive front-side components.

Therefore, in some embodiments, medium energy density with a high shot number can be used to heat the backside implanted region 101. This approach can balance the dopant activation and sheet resistance reduction while minimizing the risk of damaging the front-side components. For example, medium energy densities of about 0.7 J/cm², 0.8 J/cm², and 1.0 J/cm² can generate temperatures of about 700° C., 800° C., and 1000° C., respectively, in the backside implanted region 101. These temperatures can be sufficient for activating dopants and reducing Rs without exceeding the thermal limits of the front-side components, thus preserving the integrity of the entire device structure. In some embodiments, the NSA process P2 can be performed with varying laser pulse energy densities to optimize recrystallization and minimize thermal damage.

In some embodiments, the energy density of the NSA process P2 can be combined with the shot number to control the recrystallization range of crystal region 101a, thereby controlling the thickness T2 of the amorphous region 101b (see FIG. 11C). By adjusting both the energy density and the number of laser shots, the amorphous region recrystallizing into a crystalline state can be controlled. Specifically, a well-controlled recrystallization process can ensure that the crystal region 101a may have an optimal thickness, which in turn influences the thickness T2 of the remaining amorphous region 101 b. In some embodiments, a pulse duration of the NSA process can be less than 10 nanoseconds. In some embodiments, the NSA process P2 can be performed with varying laser pulse durations to optimize recrystallization and minimize thermal damage.

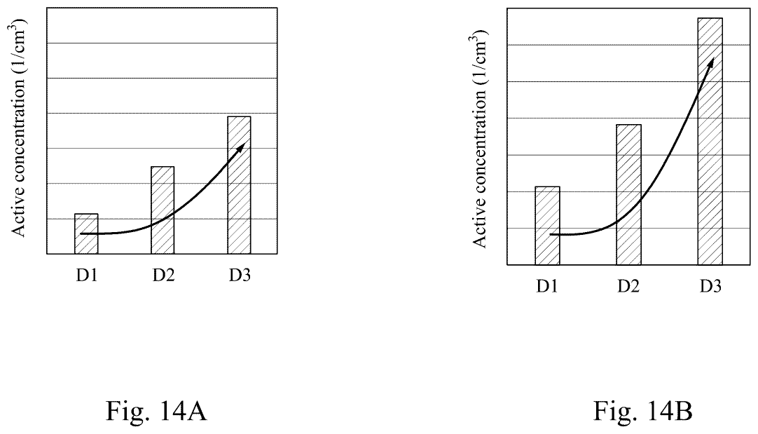

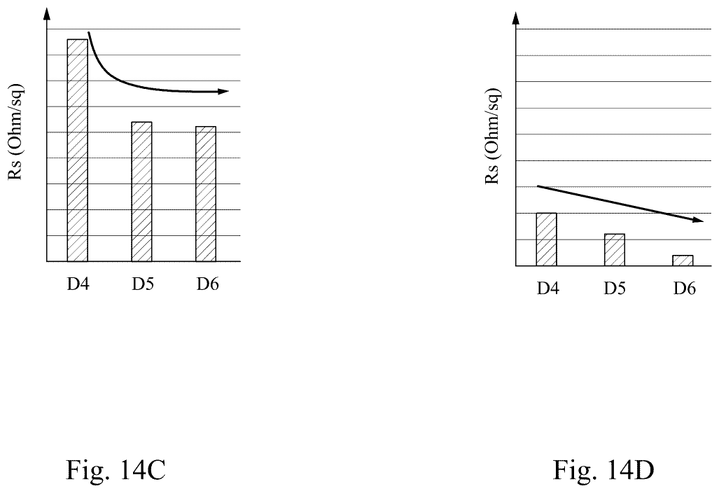

FIGS. 14A and 14B present data on the active dopant concentration in the back-side implanted region 101 of the source/drain region 100 after undergoing the NSA process P2. FIGS. 14A and 14B show results on n-type source/drain region for n-type dopants (e.g., phosphorus or arsenic). Specifically, FIG. 14A illustrates the case with a low phosphorus atomic concentration (e.g., about 3-5% in silicon phosphorus) of the backside implanted region 101, while FIG. 14B illustrates the case with a high phosphorus atomic concentration (e.g., about 6-10% in silicon phosphorus) of the backside implanted region 101. To describe the effects of different processes, there are three cases D1, D2, and D3 for each dopant concentration. The case D1 is to only perform the back-side implantation process P1. The case D2 is to perform the back-side implantation process P1 followed by a single NSA process shot. The case D3 is to perform the back-side implantation process P1 followed by multiple NSA process shots.

In both low and high phosphorus atomic concentration of the backside implanted region 101, applying the NSA process P2 can result in an increase in active dopant concentration. Specifically, FIG. 14A shows an increase of approximately 30% after a single NSA shot, and up to 70% after multiple shots. In FIG. 14B, with a higher initial dopant concentration, the active concentration increases by about 90% after multiple shots. These results can demonstrate the effectiveness of the NSA process P2 in activating dopants, regardless of the initial dopant level. The improved dopant activation can enhance the conductivity of the source/drain region 100 for optimizing the overall performance of the semiconductor device. By increasing the number of active dopants, the NSA process P2 can effectively enhance the conductivity of the source/drain region 100 for ensuring efficient current flow during device operation. The use of multiple laser shots can allow for incremental improvement in dopant activation, making it possible to fine-tune the electrical properties of the device.

FIGS. 14C and 14D present data on the sheet resistance (Rs) in the back-side implanted region 101 of the source/drain region 100 after undergoing the NSA process P2. FIGS. 14C and 14D show results on p-type source/drain region for p-type dopants (e.g., boron or gallium). Specifically, FIG. 14C represents a back-side implanted region 101 with a low germanium atomic concentration (e.g., about 40-60% in silicon germanium) of the backside implanted region 101, while FIG. 14D represents a case with a high germanium atomic concentration (e.g., about 60-80% in silicon germanium) of the backside implanted region 101. To describe the effects of different processes, there are three cases D4, D5, and D6 for each dopant concentration. The case D4 is to only perform the back-side implantation process P1 with boron. The case D5 is to perform the back-side implantation process P1 followed by a single NSA process shot with boron. The case D6 is to perform the back-side implantation process P1 followed by a single NSA process shot with gallium.

In both low and high germanium atomic concentrations of the backside implanted region 101, applying the NSA process P2 can reduce the sheet resistance (Rs), which represents the contact resistance measured after metal silicide formation. The reduction in Rs can be more pronounced when gallium is used as the dopant compared to boron. Specifically, in FIG. 14C, which shows the scenario with a low atomic concentration of p-type dopants, the sheet resistance (Rs) can be reduced by approximately 15% after the NSA process for both boron and gallium dopants. In FIG. 14D, which shows the scenario with a high atomic concentration of p-type dopants, the sheet resistance (Rs) reduction can be about 5% for boron and approximately 10% for gallium after the NSA process. These results can demonstrate that the NSA process P2 can effectively enhance the active dopant concentration and reduce the sheet resistance, regardless of the initial atomic concentration. In some embodiments, the use of gallium as a p-type dopant can provide a better reduction in sheet resistance compared to boron, which is beneficial for reducing contact resistance and improving the electrical performance of the device.

FIGS. 11D and 11E are schematic diagrams corresponding to FIG. 11C, with the difference being that FIGS. 11D and 11E show that the interface between the crystal region 101a and the amorphous region 101b in the back-side implanted region 101 may have a different profile compared to FIG. 11C. For example, as shown in FIG. 11D, the back-side surface of the crystal region 101a may protrude towards the amorphous region 101b, forming a concave curve towards the front-side at the interface between crystal region 101a and amorphous region 101b. This may be due to the fact that during recrystallization of the back-side implanted region 101 under the NSA process P2, the crystallization speed on both sides of the back-side implanted region 101 can be slower compared to the middle portion due to stress constraints on both sides, resulting in a greater thickness in the middle area of crystal region 101a and a smaller thickness in the side areas of crystal region 101a. In some embodiments, this difference can be gradual, forming a profile similar to that shown in FIG. 11D.

For example, as shown in FIG. 11E, the back-side surface of the amorphous region 101b may protrude towards the crystal region 101a, forming a concave curve away from the front-side at the interface between crystal region 101a and amorphous region 101b. This may be due to the fact that during recrystallization of the back-side implanted region 101 under the NSA process P2, the sides of the back-side implanted region 101 have more crystallization seeds, resulting in a higher probability of crystallization and causing the thickness of the side areas of crystal region 101a to be larger than the middle area. In some embodiments, this difference can be gradual, forming a profile similar to that shown in FIG. 11E.

Reference is made to FIGS. 9A, 9B, and 11F. A back-side silicide layer 233 can be formed over the back-side of the epitaxial source/drain region 100. In some embodiments, a metal silicidation process P3 can be performed on the amorphous region 101b of the epitaxial source/drain region 100 to form the back-side silicide layer 233. The metal silicidation process P3 can be to make a reaction between metal and silicon (or polycrystalline silicon). In some embodiments, a metal layer can be formed on the amorphous region 101b. Subsequently, regarding the metal silicidation process P3, a first rapid thermal annealing (RTA) process may be performed in, for example, Ar, He, N₂ or other inert atmosphere at a first temperature, such as lower than 200~300° C., to convert the deposited metal layer into metal silicide. This is followed by an etching process to remove the unreacted metal layer from. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400~500° C., thereby forming the back-side silicide layer 233 with low resistance. In some embodiments, the back-side silicide layer 233 may include titanium silicide (TiSi), nickel silicide (NiSi), cobalt silicide (CoSi), Ni—Pt, or combinations thereof.

Reference is made to FIGS. 10A and 10B. Back-side contacts (e.g., power supply voltage contacts 332) can be formed in the opening O1 and over the source/drain regions 100. In some embodiments, materials of the back-side contacts may include Cu, Co, Ru, Pt, Al, W, Ti, TaN, TiN, Molybdenum (Mo), Ruthenium (Ru), Iridium (Ir), rhodium (Rh), or any combinations thereof. Subsequently, a back-side interconnect structure 340 can be formed over the back-side contacts. The back-side interconnect structure 340 can include a back-side IMD layer 341 and a plurality of metallization layers 342 with a plurality of metallization vias or lines (e.g., power supply voltage line, such as VDD, VSS) formed in the back-side IMD layer 341. Other embodiments may contain more or fewer metallization layers and corresponding more or fewer number of vias. The metallization layers 342 may include the power supply voltage lines. In some embodiments, materials of the metallization layers 342 may include Cu, Co, Ru, Pt, Al, W, Ti, TaN, TiN, Molybdenum (Mo), Ruthenium (Ru), Iridium (Ir), rhodium (Rh), or any combinations thereof. In some embodiments, the IMD layer 341 may be formed of an oxide such as phospho-silicate glass (PSG), boro-silicate glass (BSG), boron-doped phospho-silicate glass (BPSG), tetra ethyl ortho silicate (TEOS) oxide, or the like.

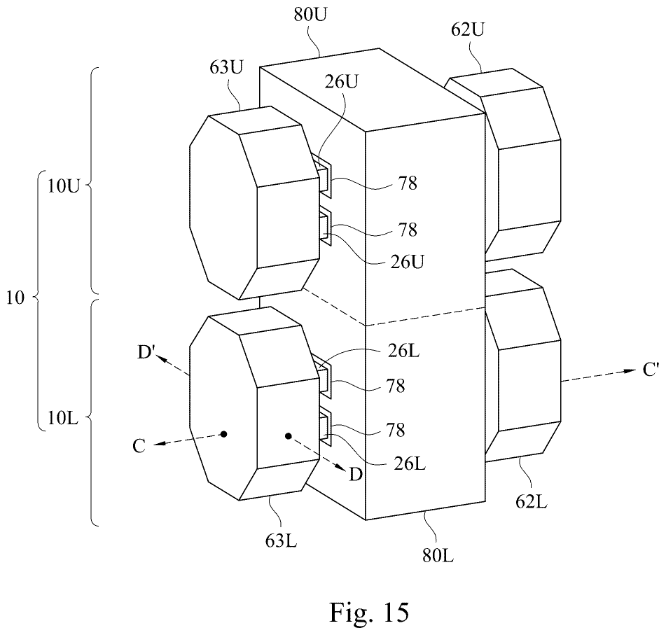

Reference is made to FIG. 15. FIG. 15 illustrates an example of a stacking transistor 10 (including FETs (transistors) 10U and 10L) in accordance with some embodiments. FIG. 15 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 63 (including lower epitaxial source/drain regions 63L and upper epitaxial source/drain regions 63U) are disposed on opposing sides of the gate dielectrics 78 and the respective gate electrodes 80. Each of the source/drain regions 63 may refer to a source or a drain, individually or collectively dependent upon the context. Isolation features (not shown) may be formed to separate desired ones of the source/drain regions 63 and/or desired ones of the gate electrodes 80.

FIG. 15 further illustrates reference cross-sections that are used in later figures. Cross-section C-C′ is a vertical cross-section that is parallel to a longitudinal axis of the semiconductor nanostructures 26 of a stacking transistor and in a direction of, for example, a current flow between the source/drain regions 63 of the stacking transistor. Cross-section D-D′ is a vertical cross-section that is perpendicular to cross-section C-C′ and extends through the source/drain regions 63 of the stacking transistor. Subsequent figures may refer to these reference cross-sections for clarity.

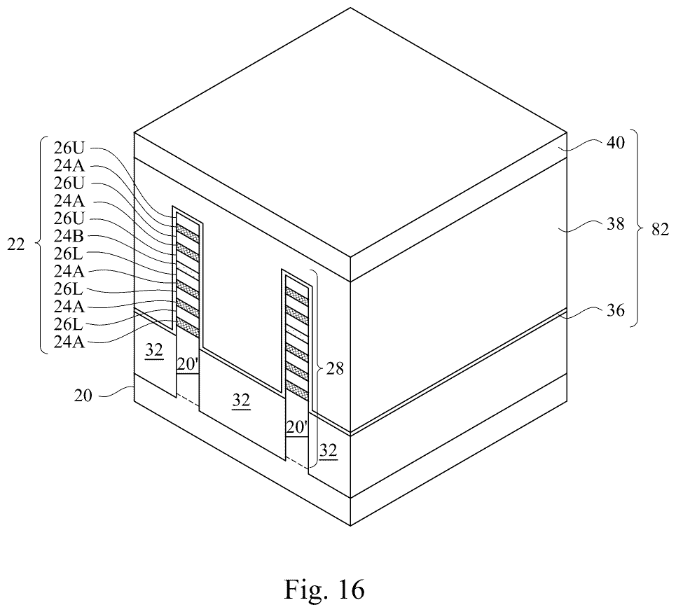

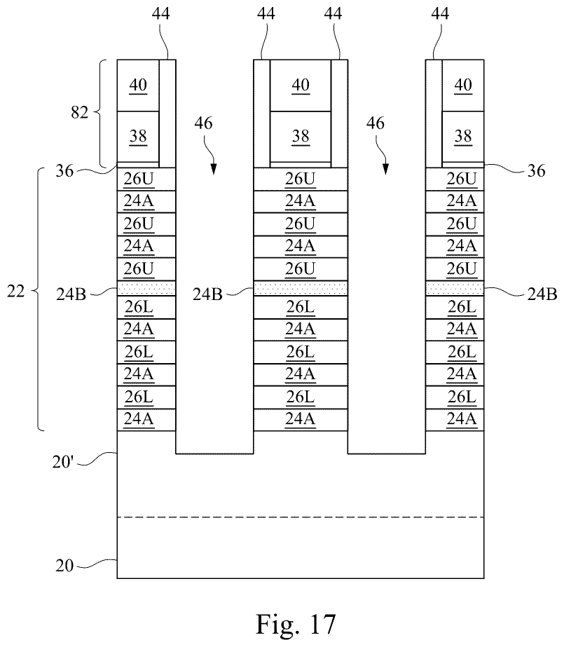

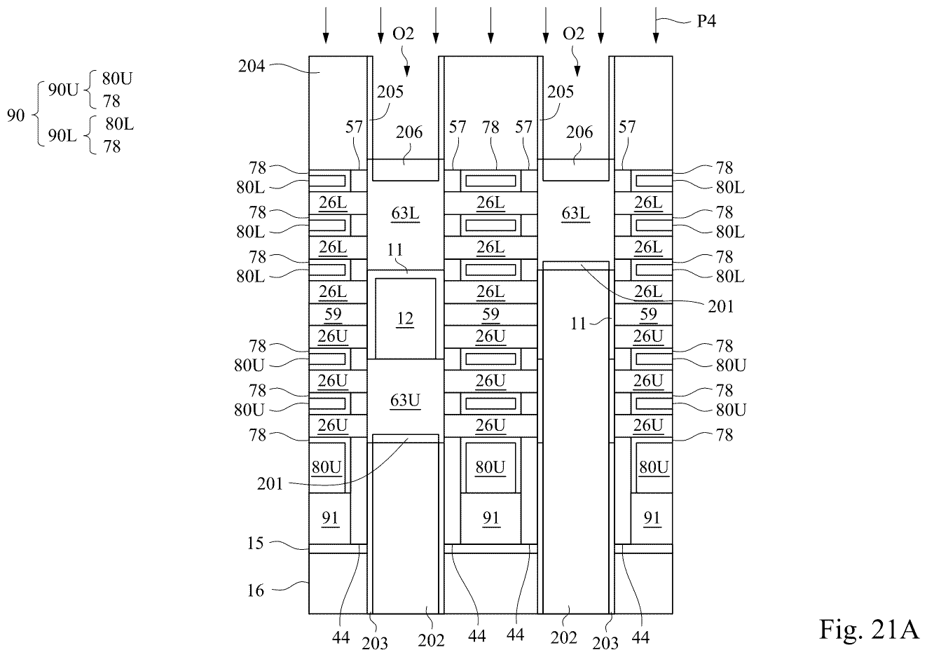

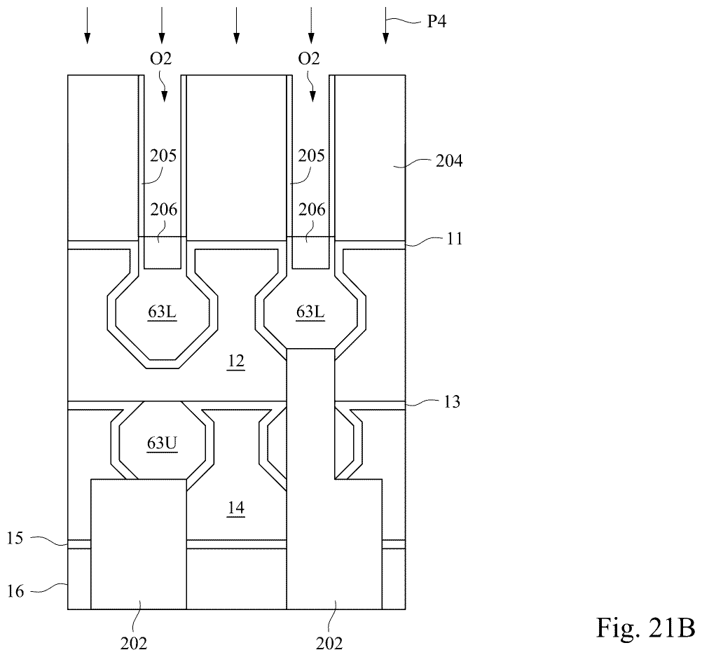

Reference is made to FIGS. 16-24B. FIGS. 16-24B illustrate cross-sectional views of intermediate stages in the formation of a semiconductor structure in accordance with some embodiments. FIGS. 17, 18, 19, 20, 21A, 22A, 23A, and 24A illustrate cross-sectional views obtained from reference cross-sections C-C′ in FIG. 15, and FIGS. 21B, 22B, 23B, and 24B illustrate cross-sectional views obtained from reference cross-sections D-D′ in FIG. 15. It is understood that additional operations can be provided before, during, and after the processes shown by FIGS. 16-24B, and some of the operations described below can be replaced or eliminated, for additional embodiments of the method. The order of the operations/processes may be interchangeable.

Reference is made to FIG. 16. A perspective view of a wafer, which includes substrate 20, is provided. In some embodiments, the substrate 20 can be substantially similar to the substrate 50 illustrated in FIGS. 1-10B in terms of it material and manufacturing methods.

Semiconductor strips 28 are formed extending upwards from the substrate 20. Each of semiconductor strips 28 includes semiconductor strip 20′ (patterned portions of the substrate 20, also referred to as semiconductor fins 20′) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor nanostructures 24B may be removed at a faster rate than the dummy semiconductor nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent process steps without significantly removing the semiconductor nanostructures 26. In some embodiments, the dummy nanostructures 24A are formed of silicon germanium, the semiconductor nanostructures 26 are formed of silicon, and the dummy nanostructures 24B may be formed of germanium or silicon germanium with a higher germanium atomic percentage than the semiconductor nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the substrate 20 to define the semiconductor strips 28, which includes the semiconductor strips 20′, the dummy nanostructures 24, and the semiconductor nanostructures 26. The semiconductor fins and the nanostructures may be patterned by any suitable method.

As also illustrated by FIG. 16, STI regions 32 are formed over the substrate 20 and between adjacent semiconductor strips 28. STI regions 32 may include a dielectric liner and a dielectric material over the dielectric liner. In some embodiments, the STI regions 32 can be substantially similar to the isolation structures 70 illustrated in FIGS. 1-10B in terms of their material and manufacturing methods.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. A dummy gate layer 38 is formed over the dummy dielectric layer 36. A mask layer 40 is formed over the dummy gate layer 38. In some embodiments, the dummy dielectric layer 36, the dummy gate layer 38, and mask layer 40 can be substantially similar to the dummy gate dielectric 82, the dummy gate electrode 84, and the patterned mask 86 illustrated in FIGS. 1-10B in terms of their material and manufacturing methods.

Reference is made to FIG. 17. Gate spacers 44 and source/drain recesses 46 are formed. First, the gate spacers 44 are formed over the multi-layer stacks 22 and on exposed sidewalls of dummy gate stacks 42. In some embodiments, the gate spacers 44 can be substantially similar to the spacers 92 illustrated in FIGS. 1-10B in terms of their material and manufacturing methods. Subsequently, source/drain recesses 46 are formed in semiconductor strips 28. The source/drain recesses 46 are formed through etching, and may extend through the multi-layer stacks 22 and into the semiconductor strips 20'. The bottom surfaces of the source/drain recesses 46 may be at a level above, below, or the same as the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

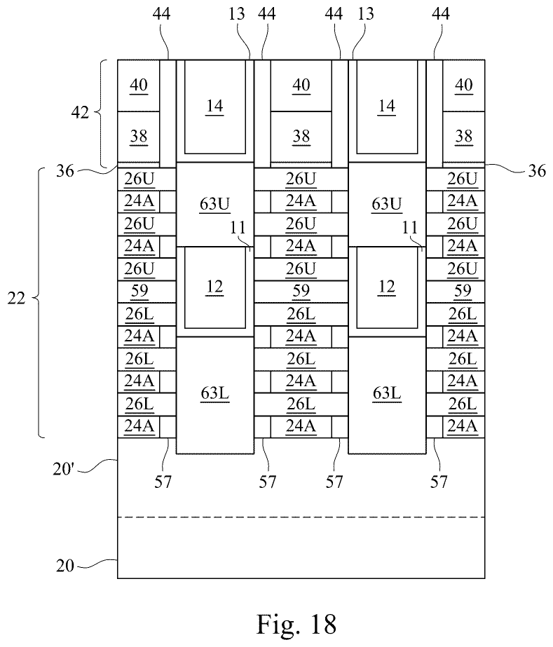

Reference is made to FIG. 18. Inner spacers 57 and dielectric isolation layers 5 can be formed. Forming the inner spacers 57 and the dielectric isolation layers 59 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 57 are formed on sidewalls of the recessed dummy nanostructures 24A, and dielectric isolation layers 59 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 57 act as isolation features between the subsequently formed source/drain regions and the subsequently formed gate structures. Further, the inner spacers 57 may be used to prevent damage to the subsequently formed source/drain regions by subsequent etch processes, such as the etch processes used to form gate structures. Dielectric isolation layers 59, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 59) and the dielectric isolation layers 59 may define the boundaries of the lower nanostructure-FETs and the upper nanostructure-FETs.

The inner spacers 57 and the dielectric isolation layers 59 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 57) and has portions remaining in between the upper and lower semiconductor nanostructures 26U and 26L (thus forming the dielectric isolation layers 59).

As also illustrated by FIG. 18, lower and upper epitaxial source/drain regions 63L and 63U are formed. The lower epitaxial source/drain regions 63L are formed in the lower portions of the source/drain recesses 46. The lower epitaxial source/drain regions 63L are in contact with the lower semiconductor nanostructures 26L and are not in contact with the upper semiconductor nanostructures 26U. Inner spacers 57 electrically insulate the lower epitaxial source/drain regions 63L from the dummy nanostructures 24A, which will be replaced with replacement gates in subsequent processes. In some embodiments, the lower and upper epitaxial source/drain regions 63L and 63U can be substantially similar to the source/drain regions 100 illustrated in FIGS. 1-10B in terms of their material and manufacturing methods. During the epitaxy of the lower epitaxial source/drain regions 63L, exposed surfaces of the upper semiconductor nanostructures 26U (e.g., sidewalls) may be masked to prevent undesired epitaxial growth on the upper semiconductor nanostructures 26U. After the lower epitaxial source/drain regions 63L are grown, the masks on the upper semiconductor nanostructures 26U may then be removed.

A first contact etch stop layer (CESL) 11 and a first ILD 12 are formed over the lower epitaxial source/drain regions 63L. The first CESL 11 may be formed of a dielectric material having a high etching selectivity from the etching of the first ILD 12. In some embodiments, the first CESL 11 and the first ILD 12 can be substantially similar to the CESL 102 and the ILD layer 104 illustrated in FIGS. 1-10B in terms of their material and manufacturing methods.

Upper epitaxial source/drain regions 63U are then formed in the upper portions of the source/drain recesses 46. The upper epitaxial source/drain regions 63U may be epitaxially grown from exposed surfaces of the upper semiconductor nanostructures 26U. The conductivity type of the upper epitaxial source/drain regions 63U may be opposite the conductivity type of the lower epitaxial source/drain regions 63L in embodiments where the stacking transistors are CFETs. For example, the upper epitaxial source/drain regions 63U may be oppositely doped from the lower epitaxial source/drain regions 63L. For example, the upper epitaxial source/drain regions 63U may be n-type and the lower epitaxial source/drain regions 63L may be p-type. Alternatively, the upper epitaxial source/drain regions 63U may be p-type and the lower epitaxial source/drain regions 63L may be n-type.

After the upper epitaxial source/drain regions 63U are formed, a second CESL 13 and a second ILD 14 are formed. The materials and the formation methods may be similar to the materials and the formation methods of first CESL 11 and first ILD 12, respectively, and are not discussed in detail herein. The formation process may include depositing the layers for the second CESL 13 and the second ILD 14, and performing a planarization process to remove the excess portion of the corresponding layers. After the planarization process, top surfaces of the second ILD 14, the gate spacers 44, and the masks 86 (if present) or the dummy gates 84 are substantially coplanar (within process variations). Accordingly, the top surfaces of the masks 40 (if present) or the dummy gates 38 are exposed through the second ILD 14. In the illustrated embodiment, the masks 40 remain after the removal process. In other embodiments, the masks 40 are removed such that the top surfaces of the dummy gates 38 are exposed through the second ILD 14.

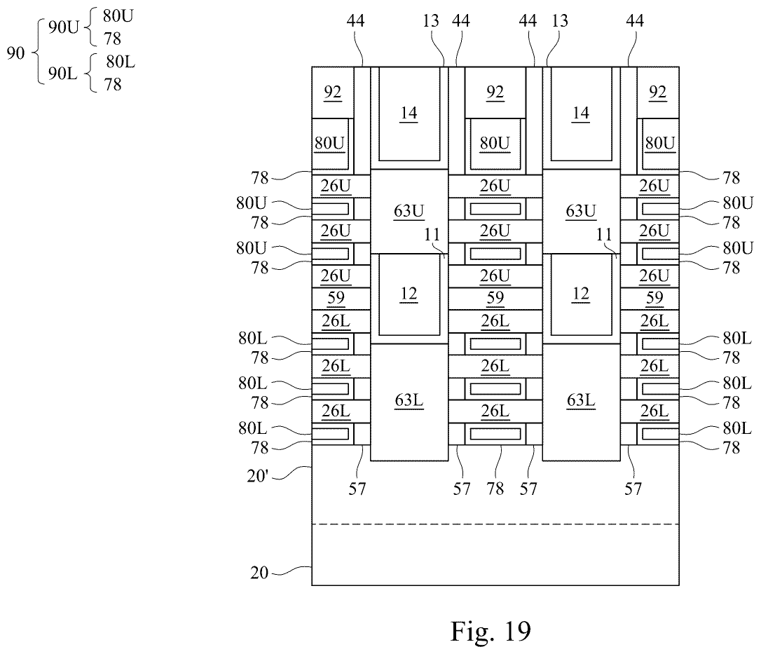

Reference is made to FIG. 19. FIG. 19 illustrates a replacement gate process to replace the dummy gate stacks 42 and the dummy nanostructures 24A with gate stacks 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A can be etched at a faster rate than the semiconductor nanostructures 26, the dielectric isolation layers 59, and the inner spacers 57. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 14. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 14. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 14, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

As also shown in FIG. 19, gate masks 91 are formed over the gate stacks 42. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 14.

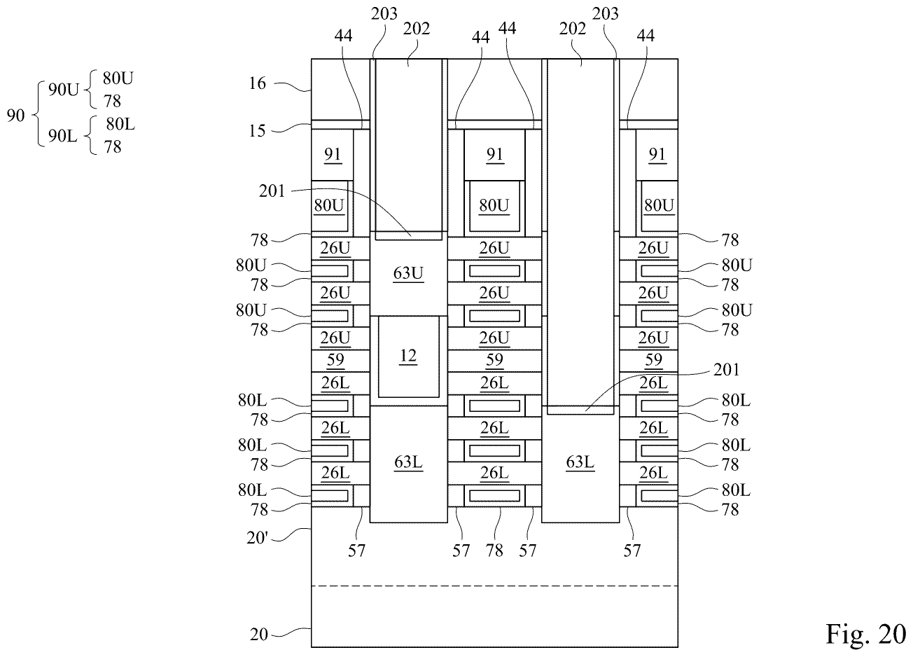

Reference is made to FIG. 20. An ESL 15 and a third ILD 16 are formed. In some embodiments, the ESL 15 may include a dielectric material having a high etching selectivity from the etching of the third ILD 16, such as, aluminum oxide, aluminum nitride, silicon oxycarbide, or the like. The third ILD 16 may be formed using flowable CVD, ALD, or the like, and the material may include PSG, BSG, BPSG, USG, or the like, which may be deposited by any suitable method, such as CVD, PECVD, or the like.

Subsequently, source/drain contacts 202 can be formed through the ESL 15, the third ILD layer 16, the second CESL 13, and the second ILD 14 and over the upper epitaxial source/drain region 63U. In some embodiments, the source/drain contacts 201 can be further formed to extend to the lower epitaxial source/drain region 63L through the upper epitaxial source/drain region 63U, the first CESL 11, and the first ILD 12. Additionally, front-side silicide layers 201 can be formed over the lower and upper epitaxial source/drain regions 63L and 63U prior to forming the source/drain contacts 202. In some embodiments, the source/drain contacts 202 and the front-side silicide layers 201 can be substantially similar to the source/drain contacts 134 and the front-side silicide layers 133 illustrated in FIGS. 1-10B in terms of their material and manufacturing methods. Spacer layer 203 can be formed to laterally surround the source/drain contacts 202. In some embodiments, the spacer layer 203 can be substantially similar to the spacer layer 160 illustrated in FIGS. 1-10B in terms of their material and manufacturing methods.

Reference is made to FIGS. 21A and 21B. The structures of FIG. 20 can be flipped upside down, and the substrate 20 and the semiconductor fins 20′ can be removed. The substrate 50 may be removed in a plurality of process operations, for example, CMP, HNA, and/or TMAH etching from the back-side of the substrate 20. Subsequently, a dielectric layer 204 can be formed over the back-side of the semiconductor structure. In some embodiments, the dielectric layer 204 can be substantially similar to the dielectric layer 152/154 illustrated in FIGS. 1-10B in terms of it material and manufacturing methods. The dielectric layer 204 can be patterned to form openings O2 in the dielectric layer 204. In some embodiments, the openings O2 can expose the underlying lower epitaxial source/drain regions 63L. A spacer layer 205 can be formed to line the sidewall of the opening O2 in the dielectric layer 204. In some embodiments, the spacer layer 205 and the opening O2 can be substantially similar to the spacer layer 160 and the opening O1 illustrated in FIGS. 1-10B in terms of their material and manufacturing methods.

A back-side implantation process P4 can be performed to modify the back-side of the lower epitaxial source/drain regions 63L, converting part of the crystalline lower epitaxial source/drain regions 63L (as shown in FIG. 11A) into a back-side implanted region 206. In the backside implanted region 206, the dopant concentration can reach levels above approximately 1×10²² atoms per cubic centimeter. The Gaussian dopant profile observed in FIG. 12A can result from the statistical nature of ion implantation. When dopants are implanted into the lower epitaxial source/drain regions 63L from the backside, they can penetrate the lattice to varying depths due to differences in energy and scattering events, leading to a peak concentration at a specific depth below the surface, with the concentration decreasing symmetrically on either side of this peak. Comparatively, the dopant concentration in the backside implanted region 101 can be higher than in other areas of the lower epitaxial source/drain regions 63L. The high dopant concentration can increase the carrier density within the silicon lattice, providing more free electrons in n-type regions or holes in p-type regions, enhancing the electrical conductivity of the region. In some embodiments, the back-side implantation process P4 can be substantially similar to the back-side implantation process P1 illustrated in FIGS. 1-10B in terms of its process and manufacturing methods.

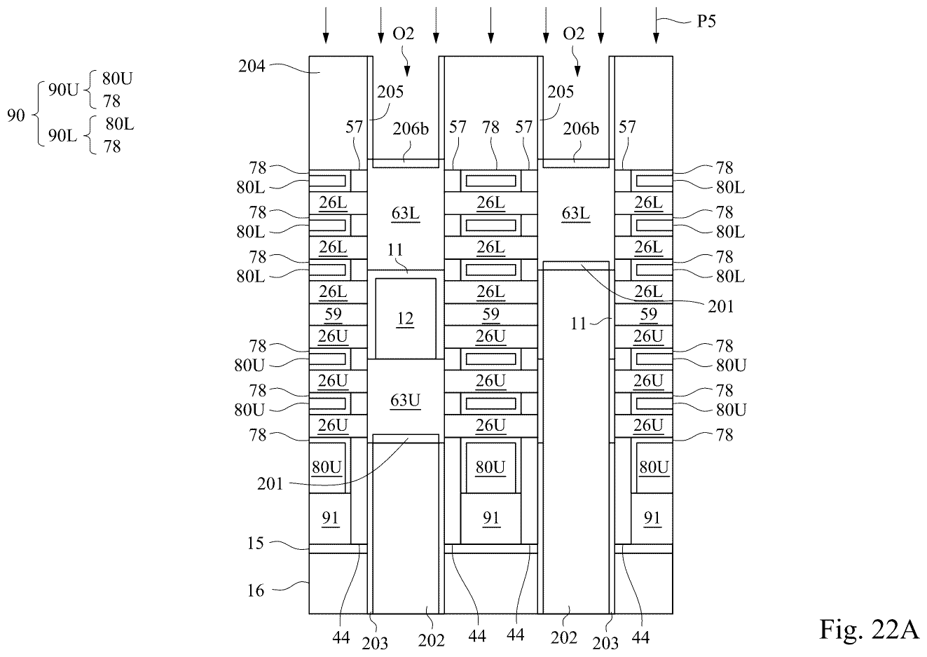

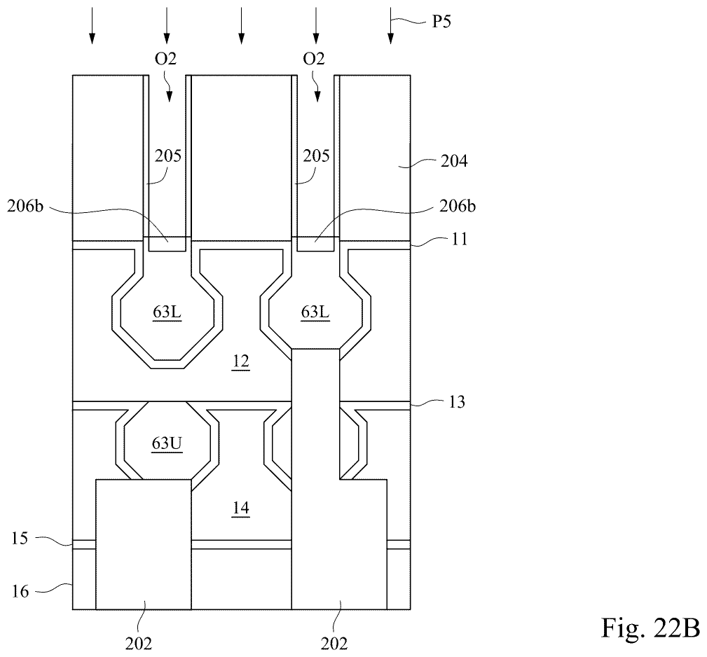

Reference is made to FIGS. 22A and 22B. A nanosecond laser annealing (NSA) process P5 can be performed to the backside implanted region 206 from the backside of the lower epitaxial source/drain region 63L. The NSA process P5 can enhance dopant activation within the backside implanted region 101. This enhancement can result in the formation of a crystalline region inside the backside implanted region 206, as depicted in FIG. 11C. The NSA process P5 can include irradiating the backside implanted region 206 with high-energy laser pulses of nanosecond duration. These rapid pulses can provide localized heating that is sufficient to activate the dopants introduced during the backside implantation process P5 without causing thermal diffusion to other parts of the device.

The activation of dopants occurs because the NSA process P5 can provide enough energy for the dopant atoms to move into substitutional positions within the silicon lattice, making them electrically active. This activation can boost the electrical conductivity of the crystalline region. The rapid heating and cooling inherent in the NSA process P5 also can initiate recrystallization of the amorphous silicon created during implantation. The high dopant concentration within the crystalline region can enhances carrier mobility and reduces resistance, thereby improving the electrical performance of the device. Additionally, as a result of the NSA process P5, the original amorphous region formed during the implantation shrinks, becoming a thinner amorphous region 206b. The thickness of the amorphous region 206b can reduce from its initial thickness (e.g., thickness T1 shown in FIG. 11B) to a smaller thickness (e.g., thickness T2 shown in FIG. 11C). The reduction in thickness can minimize the area where metal silicide can form in subsequent processing steps. A thinner amorphous region 206b can confine the silicide formation to a smaller area, which can reduce contact resistance at the metal-semiconductor interface because the silicide layer can be thinner and more uniform. In some embodiments, the NSA process P5 can be substantially similar to the NSA process P2 illustrated in FIGS. 1-10B in terms of its process and manufacturing methods.

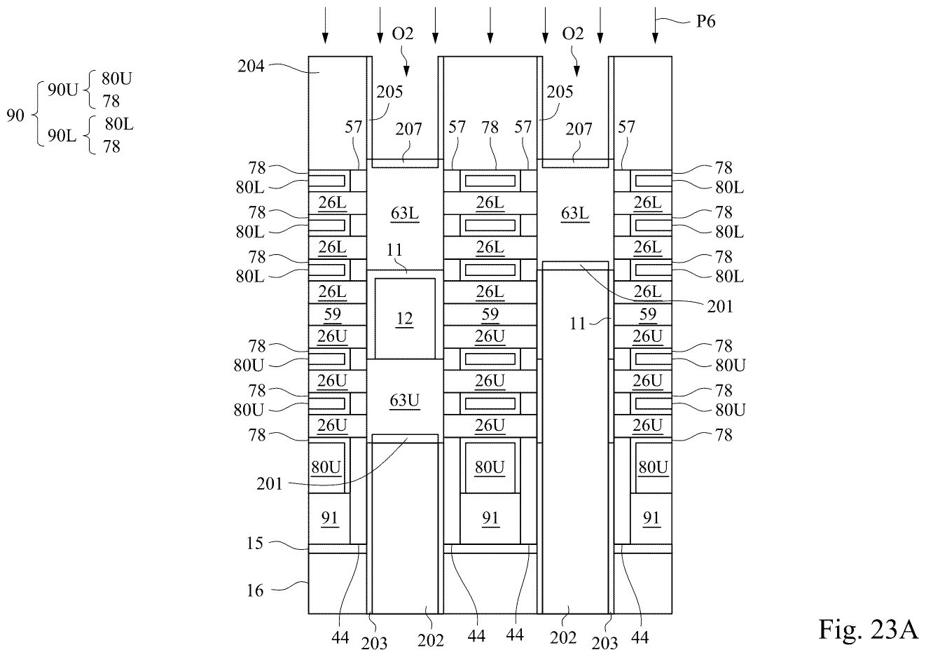

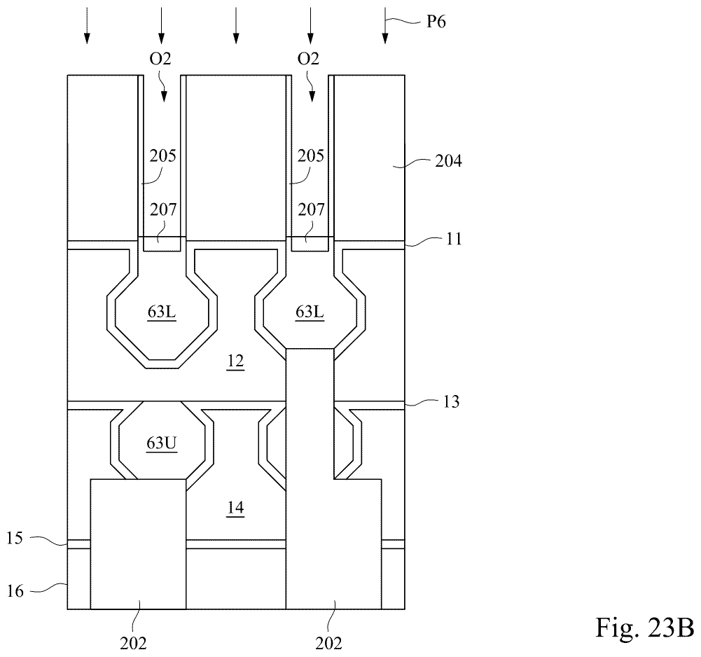

Reference is made to FIGS. 23A and 23B. A back-side silicide layer 207 can be formed over the back-side of the lower epitaxial source/drain region 63L. In some embodiments, a metal silicidation process P6 can be performed on the amorphous region 206b of the lower epitaxial source/drain region 63L to form the back-side silicide layer 207. In some embodiments, the metal silicidation process P6 and the back-side silicide layer 207 can be substantially similar to the metal silicidation process P3 and the back-side silicide layer 233 illustrated in FIGS. 1-10B in terms of their material and manufacturing methods.

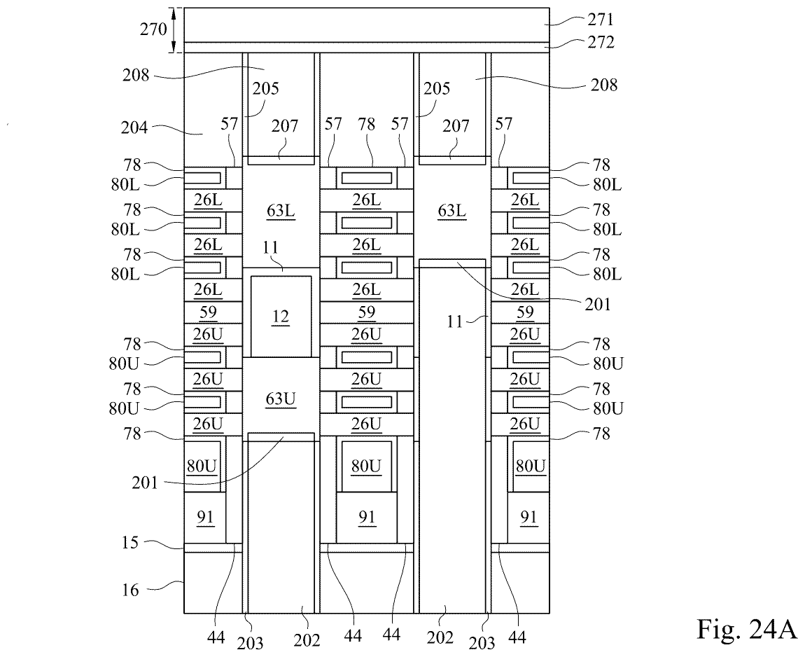

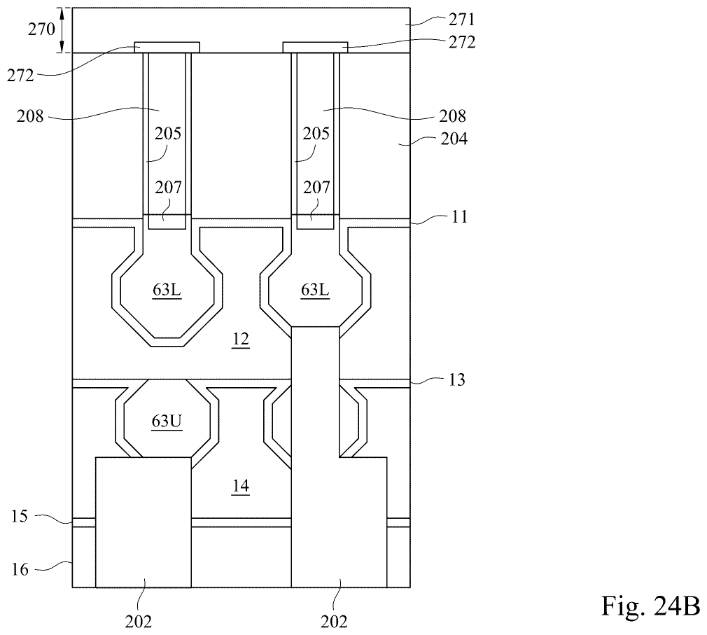

Reference is made to FIGS. 24A and 24B. Back-side contacts (e.g., power supply voltage contacts 208) can be formed in the opening O2 and over the lower epitaxial source/drain region 63L. In some embodiments, materials of the back-side contacts may include Cu, Co, Ru, Pt, Al, W, Ti, TaN, TiN, Molybdenum (Mo), Ruthenium (Ru), Iridium (Ir), rhodium (Rh), or any combinations thereof. Subsequently, a back-side interconnect structure 270 can be formed over the back-side contacts. The back-side interconnect structure 270 can include a back-side IMD layer 271 and a plurality of metallization layers 272 with a plurality of metallization vias or lines (e.g., power supply voltage line, such as VDD, VSS) formed in the back-side IMD layer 271. Other embodiments may contain more or fewer metallization layers and corresponding more or fewer number of vias. The metallization layers 272 may include the power supply voltage lines. In some embodiments, materials of the metallization layers 272 may include Cu, Co, Ru, Pt, Al, W, Ti, TaN, TiN, Molybdenum (Mo), Ruthenium (Ru), Iridium (Ir), rhodium (Rh), or any combinations thereof. In some embodiments, the IMD layer 271 may be formed of an oxide such as phospho-silicate glass (PSG), boro-silicate glass (BSG), boron-doped phospho-silicate glass (BPSG), tetra ethyl ortho silicate (TEOS) oxide, or the like.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a nanosecond laser annealing (NSA) process (see FIGS. 8A, 8B, and 11C) using a laser with a wavelength below 400 nm. This can allow for high-temperature surface heating above 900° C. within a shallow depth of less than 10 nm, effectively activating dopants without damaging front-side metal components. The NSA process can ensure a high dopant concentration at the interface between silicide and epitaxial silicon (e.g., n-type or p-type EPI). Therefore, the NSA process can effectively activate dopants without affecting deeper layers, thereby protecting the front-side metal components. In some embodiments, the NSA process can integrate into gate-all-around (GAA) and complementary field effect transistor (CFET) technologies in semiconductor devices.

Furthermore, a multi-shot NSA process can repair implant damage using a lower thermal budget and prevent damage to bottom metal layers. In some embodiments, implant species, such as boron (B), gallium (Ga), phosphorus (P), and arsenic (As), can be used in conjunction with NSA process to enhance dopant activation. In some embodiments, for medium germanium content (e.g., 40-60% in SiGe), gallium implantation followed by NSA process can offer better resistivity reduction compared to bron implantation. In high Ge content (e.g., 60-80% in SiGe), phosphorus or arsenic implantation can achieve lower sheet resistance (Rs). Therefore, this invention can effectively reduce contact resistivity in backside vias, which in turn improves the performance and reliability of semiconductor devices while operating within the thermal constraints of BEOL processes.

In some embodiments, a method includes forming a first metal silicide layer on a front-side of an epitaxial source/drain region of a transistor; after forming the first metal silicide layer, implanting a dopant into the epitaxial source/drain region from a back-side of the epitaxial source/drain region; performing a nanosecond laser annealing (NSA) process on the epitaxial source/drain region from the back-side of the epitaxial source/drain region; forming a second metal silicide on the back-side of the epitaxial source/drain region; forming a back-side contact over the second metal silicide.

In some embodiments, the NSA process is performed such that the epitaxial source/drain region has a surface heating temperature greater than about 700° C. In some embodiments, a laser of the NSA process has a wavelength less than about 400 nm. In some embodiments, implanting the dopant is performed such that the dopant has an atomic concentration greater than about 1×10²¹ atoms per cubic centimeter within the back-side of the epitaxial source/drain region. In some embodiments, the NSA process is performed to have an energy density in a range from about 0.5 to 1.3J/cm² . In some embodiments, the NSA process is performed to have a shot number greater than about 8. In some embodiments, the epitaxial source/drain region is of a p-type source/drain region and has a germanium atomic concentration in a range from about 60 to 80%. In some embodiments, the dopant comprises gallium. In some embodiments, the epitaxial source/drain region is of an n-type source/drain region and has a phosphorus atomic concentration in a range from about 6 to 10%. In some embodiments, the dopant comprises arsenic. In some embodiments, the transistor is of a nanosheet field effect transistor. In some embodiments, the transistor is of a complementary field effect transistor.

In some embodiments, a method includes forming a plurality of epitaxial structures on opposite sides of a semiconductive nanostructure; forming a gate structure wrapping around the semiconductive nanostructure and between the epitaxial structures; forming a first metal silicide layer on a front-side surface of one of the epitaxial structures; after forming first metal silicide layer, forming an amorphous region extending from a back-side surface of the one of the epitaxial structures toward the front-side surface of the one of the epitaxial structures; performing a nanosecond laser annealing (NSA) process on the amorphous region from the back-side surface of the one of the epitaxial structures, wherein the NSA process recrystallizes the amorphous region; performing a metal silicidation process on the thinned amorphous region, such that the thinned amorphous region is converted to a second metal silicide layer; forming a metal contact over the second metal silicide layer.

In some embodiments, the NSA process is performed to thin a thickness of the amorphous region to less than half of an initial thickness of the amorphous region. In some embodiments, a laser of the NSA process has a wavelength less than about 400 nm. In some embodiments, the NSA process is performed such that a surface heating temperature on the amorphous region is greater than about 700° C. In some embodiments, the metal silicidation process is performed under a temperature lower about 400° C. In some embodiments, the NSA process is performed as a multi-shot laser annealing.

In some embodiments, a method includes forming a first metal silicide layer on a front-side of a top-tier epitaxial source/drain region of a top-tier transistor; implanting a dopant into a bottom-tier epitaxial source/drain region of a bottom-tier transistor located below the top-tier transistor, from a back-side of the bottom-tier epitaxial source/drain region; performing a multi-shot nanosecond laser annealing (NSA) process on the bottom-tier epitaxial source/drain region from the back-side of the bottom-tier epitaxial source/drain region, wherein the multi-shot NSA process uses a laser with a wavelength of less than about 400 nm; forming a second metal silicide layer on the back-side of the bottom-tier epitaxial source/drain region; forming a metal contact over the second metal silicide layer.

In some embodiments, the bottom-tier epitaxial source/drain region comprises a silicon-germanium material with a germanium atomic concentration between about 40% and 80%. In some embodiments, the dopant comprises a p-type dopant selected from a group comprising of boron and gallium. In some embodiments, the multi-shot NSA process comprises more than 8 laser shots. In some embodiments, the multi-shot NSA process recrystallizes an amorphous region formed during the implanting the dopant, thereby reducing a thickness of the amorphous region to less than half of an initial thickness of the amorphous region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first metal silicide layer on a front-side of an epitaxial source/drain region of a transistor;
after forming the first metal silicide layer, implanting a dopant into the epitaxial source/drain region from a back-side of the epitaxial source/drain region;
performing a nanosecond laser annealing (NSA) process on the epitaxial source/drain region from the back-side of the epitaxial source/drain region;
forming a second metal silicide on the back-side of the epitaxial source/drain region; and
forming a back-side contact over the second metal silicide.

2. The method of claim 1, wherein a laser of the NSA process has a wavelength less than about 400 nm.

3. The method of claim 1, wherein implanting the dopant is performed such that the dopant has an atomic concentration greater than about 1×10²¹ atoms per cubic centimeter within the back-side of the epitaxial source/drain region.

4. The method of claim 1, wherein the NSA process is performed to have an energy density in a range from about 0.5 to 1.3 J/cm².

5. The method of claim 1, wherein the NSA process is performed such that the epitaxial source/drain region has a surface heating temperature greater than about 700°C.

6. The method of claim 1, wherein the epitaxial source/drain region is of a p-type source/drain region and has a germanium atomic concentration in a range from about 60 to 80%.

7. The method of claim 6, wherein the dopant comprises gallium.

8. The method of claim 1, wherein the epitaxial source/drain region is of an n-type source/drain region and has a phosphorus atomic concentration in a range from about 6 to 10%.

9. The method of claim 8, wherein the dopant comprises arsenic.

10. The method of claim 1, wherein the transistor is of a nanosheet field effect transistor.

11. A method, comprising:
forming a plurality of epitaxial structures on opposite sides of a semiconductive nanostructure;
forming a gate structure wrapping around the semiconductive nanostructure and between the epitaxial structures;
forming a first metal silicide layer on a front-side surface of one of the epitaxial structures;
after forming first metal silicide layer, forming an amorphous region extending from a back-side surface of the one of the epitaxial structures toward the front-side surface of the one of the epitaxial structures;
performing a nanosecond laser annealing (NSA) process on the amorphous region from the back-side surface of the one of the epitaxial structures, wherein the NSA process recrystallizes the amorphous region;
performing a metal silicidation process on the thinned amorphous region, such that the thinned amorphous region is converted to a second metal silicide layer; and
forming a metal contact over the second metal silicide layer.

12. The method of claim 11, wherein the NSA process is performed to thin a thickness of the amorphous region to less than half of an initial thickness of the amorphous region.

13. The method of claim 11, wherein the NSA process is performed such that a surface heating temperature on the amorphous region is greater than about 700°C.

14. The method of claim 11, wherein the metal silicidation process is performed under a temperature lower about 400°C.

15. The method of claim 11, wherein the NSA process is performed as a multi-shot laser annealing.

16. A method, comprising:
forming a first metal silicide layer on a front-side of a top-tier epitaxial source/drain region of a top-tier transistor;
implanting a dopant into a bottom-tier epitaxial source/drain region of a bottom-tier transistor located below the top-tier transistor, from a back-side of the bottom-tier epitaxial source/drain region;
performing a multi-shot nanosecond laser annealing (NSA) process on the bottom-tier epitaxial source/drain region from the back-side of the bottom-tier epitaxial source/drain region, wherein the multi-shot NSA process uses a laser with a wavelength of less than about 400 nm;
forming a second metal silicide layer on the back-side of the bottom-tier epitaxial source/drain region; and
forming a metal contact over the second metal silicide layer.

17. The method of claim 16, wherein the bottom-tier epitaxial source/drain region comprises a silicon-germanium material with a germanium atomic concentration between about 40% and 80%.

18. The method of claim 16, wherein the dopant comprises a p-type dopant selected from a group comprising of boron and gallium.

19. The method of claim 16, wherein the multi-shot NSA process comprises more than 8 laser shots.

20. The method of claim 16, wherein the multi-shot NSA process recrystallizes an amorphous region formed during the implanting the dopant, thereby reducing a thickness of the amorphous region to less than half of an initial thickness of the amorphous region.
